(19) United States
(12) Patent Application Publication
(10) Pub. No.: US 2025/0301699 A1
(43) Pub. Date: Sep. 25, 2025

(54) GATE TRENCH POWER SEMICONDUCTOR DEVICES HAVING TRENCH SHIELDING REGIONS AND METHODS OF FORMING THE SAME

(71) Applicant: Wolfspeed, Inc., Durham, NC (US)

(72) Inventors: Madankumar Sampath, Durham, NC (US); Woongsun Kim, Cary, NC (US); Naeem Islam, Morrisville, NC (US); Sei-Hyung Ryu, Cary, NC (US)

(21) Appl. No.: 18/610,394

(22) Filed: Mar. 20, 2024

(51) Int. Cl. H01L 29/78; H01L 29/06; H01L 29/16; H01L 29/423

(52) U.S. Cl. CPC H10D 30/668; H10D 62/106; H10D 62/8325; H10D 64/513

(57) ABSTRACT

A semiconductor device comprises a semiconductor layer structure that comprises a drift region having a first conductivity type and a trench shielding region having a second conductivity type, and a gate trench extending in a longitudinal direction in the semiconductor layer structure. The trench shielding region extends in the longitudinal direction underneath the gate trench, and at least a portion of the trench shielding region comprises sidewalls that angle inwardly with increasing distance from the gate trench.

### FIELD OF THE INVENTION

The present invention relates to power semiconductor devices and, more particularly, to power semiconductor devices having gate trenches and to methods of fabricating such devices.

### BACKGROUND OF THE INVENTION

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure and are separated by a channel region. A gate electrode (which may act as the gate terminal or be electrically connected to the gate terminal) is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different from each other. Thus, if a first region of a device has a first conductivity type and a second region of the device has a second conductivity type, this means either that the first region has n-type conductivity and the second region has p-type conductivity or, alternatively, that the first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) and combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the upper surface of the semiconductor layer structure and the drain may be on the lower surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a planar gate electrode design in which the gate electrode of the transistor is formed on top of the semiconductor layer structure or, alternatively, may have the gate electrode in a gate trench within the semiconductor layer structure, which are typically referred to as gate trench MOSFETs. With the planar gate electrode design, the channel region of each unit cell transistor is horizontally disposed underneath the gate electrode. In contrast, in the gate trench MOSFET design, the channels are typically vertically disposed adjacent sidewalls of the gate electrodes. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer, and thus increasing the thickness of the gate oxide layer is typically not an acceptable way of increasing the lifetime of the gate oxide layer.

### SUMMARY OF THE INVENTION

Pursuant to some embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure. The trench shielding region extends in the longitudinal direction underneath the gate trench, and at least a portion of the trench shielding region comprises sidewalls that angle inwardly with increasing distance from the gate trench.

In some embodiments, the portion of the trench shielding region comprises at least a lower half of the trench shielding region.

In some embodiments, the sidewalls of the portion of the trench shielding region angle inwardly with increasing distance from the gate trench in a direction perpendicular to a lower surface of the semiconductor layer structure.

In some embodiments, a maximum width of the portion of the trench shielding region is less than or equal to a maximum width of the gate trench.

In some embodiments, the semiconductor layer structure further comprises first and second support shields having the second conductivity type and extending in the longitudinal direction on first and second sides of the gate trench, respectively.

In some embodiments, a portion of the drift region is between the first support shield and the trench shielding region and has a width that is substantially constant or increases with increasing depth in the semiconductor layer structure.

In some embodiments, the width of the portion of the drift region increases with increasing depth in the semiconductor layer structure.

In some embodiments, the first and second support shields have respective widths that are substantially constant or decrease with increasing depth in the semiconductor layer structure.

In some embodiments, the first and second support shields have respective widths that increase with increasing depth in the semiconductor layer structure.

In some embodiments, an upper portion of the trench shielding region is between the gate trench and a lower portion of the trench shielding region and has a higher second conductivity type doping concentration than the lower portion of the trench shielding region.

In some embodiments, the semiconductor device further comprises a gate oxide layer and a gate electrode in the gate trench. The semiconductor layer structure further comprises a well region having the second conductivity type on the drift region and a source region having the first conductivity type on the well region.

In some embodiments, the drift region comprises silicon carbide.

Pursuant to further embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure. The trench shielding region extends underneath the gate trench in the longitudinal direction, the trench shielding region comprising endwalls that oppose each other along the longitudinal direction and are oblique with respect to a lower surface of the semiconductor layer structure.

In some embodiments, the endwalls of the trench shielding region extend substantially parallel to each other.

In some embodiments, the endwalls of the trench shielding region are adjacent an inactive region of the semiconductor device.

In some embodiments, one of the endwalls of the trench shielding region extends past an endwall of the gate trench in the longitudinal direction.

In some embodiments, one of the endwalls of the trench shielding region comprises a lower portion that is free of vertical overlap with the gate trench.

Pursuant to additional embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure. The trench shielding region extends underneath the gate trench in the longitudinal direction, the trench shielding region comprising an endwall that extends past an endwall of the gate trench in the longitudinal direction.

In some embodiments, the endwall of the trench shielding region is one of a pair of endwalls of the trench shielding region that oppose each other along the longitudinal direction and are oblique with respect to a lower surface of the semiconductor layer structure.

In some embodiments, the endwall of the trench shielding region comprises a lower portion that is free of vertical overlap with the gate trench.

In some embodiments, the endwall of the trench shielding region is adjacent an inactive region of the semiconductor device.

In some embodiments, the endwall of the trench shielding region is oblique with respect to a lower surface of the semiconductor layer structure.

Pursuant to still further embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure. The trench shielding region extends underneath the gate trench in the longitudinal direction, and an average width of an upper half of the trench shielding region is greater than an average width of a lower half of the trench shielding region.

In some embodiments, an upper portion of the trench shielding region is between the gate trench and a lower portion of the trench shielding region and has a higher second conductivity type doping concentration than the lower portion of the trench shielding region.

In some embodiments, the semiconductor layer structure further comprises first and second support shields having the second conductivity type and extending in the longitudinal direction on first and second sides of the gate trench, respectively.

In some embodiments, at least a portion of the trench shielding region comprises sidewalls that angle inwardly with increasing distance from the gate trench.

Pursuant to yet additional embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure. The trench shielding region extends underneath the gate trench in the longitudinal direction and comprises an endwall that extends along a crystallographic axis of the semiconductor layer structure.

In some embodiments, the crystallographic axis is one of <11-23>, <−1-123>, <1-213>, <−12-13>, <2-1-13> or <−2113> crystallographic axes.

In some embodiments, the crystallographic axis is a <0001> crystallographic axis.

In some embodiments, the trench shielding region extends into the drift region, and the drift region comprises silicon carbide.

Pursuant to still other embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure on the trench shielding region. The trench shielding region extends underneath the gate trench into the drift region to provide a super junction structure in the drift region.

In some embodiments, at least a portion of the trench shielding region comprises sidewalls that angle inwardly with increasing distance from the gate trench.

In some embodiments, at least a portion of the trench shielding region comprises sidewalls that extend substantially perpendicular to a lower surface of the semiconductor layer structure with increasing distance from the gate trench.

In some embodiments, an upper portion of the trench shielding region is between the gate trench and a lower portion of the trench shielding region and has a higher second conductivity type doping concentration than the lower portion of the trench shielding region.

In some embodiments, the trench shielding region extends from a bottom surface of the gate trench into the drift region to a depth of at least 4 microns.

Pursuant to still additional embodiments of the present invention, semiconductor devices are provided that comprise a semiconductor layer structure that comprises a drift region having a first conductivity type and a trench shielding region having a second conductivity type, and a gate trench extending in a longitudinal direction in the semiconductor layer structure. The trench shielding region extends underneath the gate trench in the longitudinal direction, and at least a portion of the trench shielding region comprises sidewalls that extend substantially perpendicular to a lower surface of the semiconductor layer structure with increasing distance from the gate trench.

In some embodiments, the trench shielding region further comprises endwalls that oppose each other in the longitudinal direction and are oblique with respect to the lower surface of the semiconductor layer structure.

In some embodiments, an upper portion of the trench shielding region is between the gate trench and a lower portion of the trench shielding region and has a higher second conductivity type doping concentration than the lower portion of the trench shielding region.

Pursuant to yet other embodiments of the present invention, methods of fabricating semiconductor devices are provided. These methods comprise providing a semiconductor layer structure that comprises a drift region having a first conductivity type, forming a gate trench that extends in a longitudinal direction in the semiconductor layer structure, and forming a trench shielding region by implanting second conductivity type dopants into the semiconductor layer structure using a channeled ion implantation process. The trench shielding region extends underneath the gate trench in the longitudinal direction.

In some embodiments, the channeled ion implantation process is performed along a crystallographic axis of the semiconductor layer structure.

In some embodiments, the drift region comprises silicon carbide, and the crystallographic axis is one of <0001>, <11-23>, <−1-123>, <1-213>, <−12-13>, <2-1-13, <−2113>, or <11-20> crystallographic axes.

In some embodiments, the trench shielding region is formed after the gate trench.

In some embodiments, the trench shielding region is formed by implanting the second conductivity type dopants into the gate trench.

In some embodiments, the trench shielding region is formed before the gate trench.

In some embodiments, the method further comprises forming a well region on the drift region by implanting second conductivity type dopants into the semiconductor layer structure using a channeled ion implantation process.

In some embodiments, the well region is formed simultaneously with the trench shielding region using the same channeled ion implantation process.

In some embodiments, the method further comprises implanting second conductivity type dopants into an upper portion of the trench shielding region using a random ion implantation process.

In some embodiments, the upper portion of the trench shielding region has a higher second conductivity type doping concentration than a lower portion of the trench shielding region.

In some embodiments, the method further comprises forming first and second support shields that extend in the longitudinal direction on first and second sides of the gate trench, respectively, by implanting second conductivity type dopants into the semiconductor layer structure using a channeled ion implantation process.

In some embodiments, the method further comprises forming first and second support shields that extend in the longitudinal direction on first and second sides of the gate trench, respectively, by implanting second conductivity type dopants into the semiconductor layer structure using a random ion implantation process.

Pursuant to yet further embodiments of the present invention, methods of fabricating semiconductor devices are provided. These methods comprise providing a semiconductor layer structure that comprises a drift region having a first conductivity type, forming a gate trench that extends in a longitudinal direction in the semiconductor layer structure, and simultaneously forming a well region and a trench shielding region by implanting second conductivity type dopants into the semiconductor layer structure using a channeled ion implantation process. The well region is on the drift region, and the trench shielding region extends underneath the gate trench in the longitudinal direction.

Pursuant to still further embodiments of the present invention, methods of fabricating semiconductor devices are provided. These methods comprise providing a semiconductor layer structure that comprises a drift region having a first conductivity type, forming a gate trench that extends in a longitudinal direction in the semiconductor layer structure, and forming a trench shielding region by implanting second conductivity type dopants into the semiconductor layer structure using both a channeled ion implantation process and a random ion implantation process. The trench shielding region extends underneath the gate trench in the longitudinal direction.

In some embodiments, after using both the channeled ion implantation process and the random ion implantation process to form the trench shielding region, an upper portion of the trench shielding region has a higher second conductivity type doping concentration than a lower portion of the trench shielding region.

Pursuant to yet additional embodiments of the present invention, methods of fabricating semiconductor devices are provided. These methods comprise providing a semiconductor layer structure that comprises a drift region having a first conductivity type, forming a gate trench that extends in a longitudinal direction in the semiconductor layer structure, and forming a trench shielding region by implanting second conductivity type dopants into the gate trench such that the trench shielding region is aligned with the gate trench in the longitudinal direction. The trench shielding region extends underneath the gate trench into the drift region to provide a super junction structure in the drift region.

In some embodiments, forming the trench shielding region comprises performing a channeled ion implantation process.

In some embodiments, forming the trench shielding region comprises performing both a channeled ion implantation process and a random ion implantation process.

### BRIEF DESCRIPTION OF THE DRAWINGS

FIG. 1 is a semi-log graph illustrating the relationship between the lifetime of the gate oxide layer as a function of applied electric field strength.

FIG. 2 is a schematic cross-sectional view of a unit cell of a gate trench silicon carbide power MOSFET having a trench shielding region.

FIG. 3A is a schematic top view of a gate trench silicon carbide power MOSFET according to some embodiments of the present invention.

FIG. 3B is a schematic top view of the gate trench silicon carbide power MOSFET of FIG. 3A with various of the upper metal and dielectric layers removed.

FIG. 3C is a schematic cross-sectional view of the gate trench silicon carbide power MOSFET of FIGS. 3A-3B that is taken along line A-A of FIG. 3A.

FIG. 3D is a schematic cross-sectional view of the gate trench silicon carbide power MOSFET of FIGS. 3A-3C that is taken along line B-B of FIG. 3A.

FIGS. 4-6, 7A-7B, 8A-8B, 9A-9B, 10A-10B, 11A-11B, and 12A-12B are schematic cross-sectional views of gate trench silicon carbide power MOSFETs that are modified versions of the gate trench silicon carbide power MOSFET of FIGS. 3A-3D, according to some embodiments of the present invention.

FIGS. 13A-13F are schematic cross-sectional views illustrating a method of fabricating a gate trench silicon carbide power MOSFET according to some embodiments of the present invention.

FIGS. 14A-14C are schematic cross-sectional views illustrating a method of fabricating a gate trench silicon carbide power MOSFET according to some embodiments of the present invention.

FIGS. 15A-15B are schematic cross-sectional views illustrating a method of fabricating a gate trench silicon carbide power MOSFET according to some embodiments of the present invention.

FIGS. 16A-16E are schematic cross-sectional views illustrating a method of fabricating a gate trench silicon carbide power MOSFET according to some embodiments of the present invention.

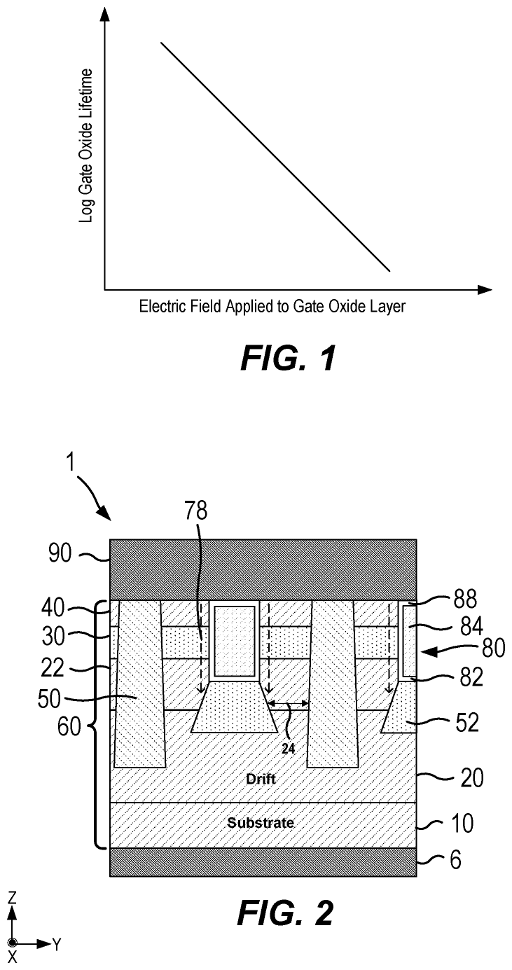

### DETAILED DESCRIPTION

Vertical silicon carbide based power semiconductor devices that have gate trenches such as vertical power MOSFETs and IGBTs are attractive for many applications due to their inherent lower specific on-resistance, which may result in more efficient operation for power switching operations. The channels in a gate trench vertical power device are formed on the sidewalls of the gate trenches, and hence are vertical channels. The carrier mobility in these vertically-oriented sidewall channels may be about 2-4 times higher than the corresponding carrier mobility in the horizontal channel of a planar gate (i.e., non-gate trench) vertical power device, which results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches. The high electric fields degrade the gate oxide layer over time and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the lower surface of the semiconductor layer structure) toward the upper surface of the semiconductor layer structure. Thus, under reverse blocking operation, the bottom portion of the gate dielectric layer experiences the highest electric field levels. Due to electric field crowding effects, the electric field levels in the lower “corners” of the gate oxide layer at the bottom edges of the gate trench may be particularly high (i.e., the portions of the gate oxide layer that cover the region where the sidewalls of the gate trench merge into the bottom of the gate trench). Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer. Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

More recently, gate trench power MOSFETs have been suggested that include so-called “trench shielding regions” (also called “trench shields” or “bottom shields”). The trench shielding regions are provided underneath the gate trenches of gate trench power MOSFETs in order to reduce the electric field levels in the gate oxide layer during reverse blocking operation. These trench shielding regions may be formed by doping the portions of the semiconductor layer structure underneath the gate trenches with dopants having the same conductivity type as the dopants included in the channel regions of the device. For example, the trench shielding regions may be formed via one or more ion implantation processes in which p-type dopant ions (for an n-type MOSFET) are implanted into the semiconductor layer structure underneath the gate trenches. The trench shielding regions may, for example, extend downwardly 0.5 to 1.0 microns or more from the bottoms of the gate trenches into the semiconductor layer structure of the device, and are moderately to highly doped regions. The trench shielding regions may be electrically connected to the source terminal of the MOSFET by p-type trench shield connection patterns. These trench shield connection patterns may be in and/or outside the active region of the device.

FIG. 2 is a schematic cross-sectional view of a portion of a silicon carbide power MOSFET 1 that includes trench shielding regions 52. The cross-section of FIG. 2 shows one full unit cell of the MOSFET 1 and portions of two adjacent unit cells. As shown in FIG. 2, the MOSFET 1 includes a silicon carbide semiconductor substrate 10. A silicon carbide drift region 20 is provided on the upper surface of the substrate 10. Silicon carbide JFET regions 22 are formed in the upper portion of the drift region 20. For illustrative purposes, the JFET regions 22 are shown on the drift region 20 in FIG. 2. However, it will be understood that the JFET regions 22 can be considered on or in an upper portion of the drift region 20 and thus may be considered as part of the drift region 20. In some embodiments, the JFET regions 22 may be more heavily doped than the remainder of the drift region 20. In some other embodiments, the JFET regions 22 may have a same doping concentration as the remainder of the drift region 20. Silicon carbide well regions 30 are provided on upper surfaces of the JFET regions 22. Silicon carbide source regions 40 are formed on upper portions of the well regions 30. Channels regions of the MOSFET 1 may be formed in a portion of each well region 30 that is adjacent a gate trench 80. The channel regions may provide channels or conduction paths 78 (shown by dashed arrows) that allow a path for current to flow from the source regions 40 to the drift region 20 during on-state operation. The substrate 10, the drift region 20, the JFET regions 22, the well regions 30, and the source regions 40 are part of a semiconductor layer structure 60 of the MOSFET 1. The substrate 10, the drift region 20, the JFET regions 22, and the source regions 40 have a first conductivity type, and the well regions 30 have a second conductivity type. For example, when the MOSFET 1 is an n-type MOSFET, the substrate 10, the drift region 20, the JFET regions 22, and the source regions 40 have n-type conductivity, and the well regions 30 have p-type conductivity. As another example, when the MOSFET 1 is a p-type MOSFET, the substrate 10, the drift region 20, the JFET regions 22, and the source regions 40 have p-type conductivity, and the well regions 30 have n-type conductivity. Hereinafter, embodiments of the present invention will be discussed with reference to n-type MOSFETs. However, it will be understood that embodiments of the present invention are not limited thereto.

The semiconductor layer structure 60 further includes p-type support shields 50 that extend downwardly from an upper portion (e.g., the upper surface) of the semiconductor layer structure 60. The p-type support shields 50 may be moderately or heavily doped silicon carbide regions and have a same conductivity type as the well regions 30.

A plurality of gate trenches 80 are formed in the upper portion of the semiconductor layer structure 60. The gate trenches 80 may extend longitudinally in a first direction X (which may also be referred to herein as a longitudinal direction). The formation of the gate trenches 80 may convert a well layer and a source layer into the plurality of well regions 30 and the plurality of source regions 40, respectively. A gate oxide layer 82 is formed conformally within each gate trench 80, and gate electrodes 84 are formed in the gate trenches 80 on the gate oxide layers 82. Intermetal dielectric layers 88 cover the gate electrodes 84. A source metallization layer 90 is formed on the intermetal dielectric layers 88 and on the n-type source regions 40 and upper portions of the p-type support shields 50. A drain contact 6 is formed on the lower surface of the substrate 10.

The semiconductor layer structure 60 also includes p-type trench shielding regions 52 that are formed underneath the respective gate trenches 80. The p-type trench shielding regions 52 extend in the first direction X underneath the respective gate trenches 80 for all or substantially all of the length of the gate trenches 80 (i.e., into the page in FIG. 2). The p-type trench shielding regions 52 may be moderately or heavily doped silicon carbide regions and have a same conductivity type as the well regions 30. The p-type support shields 50 and the p-type trench shielding regions 52 act to reduce the electric field levels that form in the gate oxide layers 82 during reverse blocking operation of the MOSFET 1.

The p-type support shields 50 may extend downwardly part or all of the way through the JFET regions 22. Likewise, the gate trenches 80 and the p-type trench shielding regions 52 thereunder may also extend downwardly part or all of the way through the JFET regions 22. As a result, the JFET regions 22 may horizontally overlap the p-type support shields 50 and one or both of the gate trenches 80 and the p-type trench shielding regions 52. As used herein, two elements of a semiconductor device are considered to “horizontally overlap” if an axis that is parallel to the major surfaces of a semiconductor layer structure of the semiconductor device intersects both elements. The major surfaces of the semiconductor layer structure may also be referred to herein as a lower surface and an upper surface of the semiconductor layer structure.

As shown in FIG. 2, a width of a JFET region 22 between a p-type trench shielding region 52 and an adjacent p-type support shield 50 may be referred to as a JFET gap 24. The JFET gaps 24 may be taken in a second direction Y that intersects the first direction X. As a p-type trench shielding region 52 and an adjacent p-type support shield 50 extend in a depth direction (e.g., a third direction Z) in the semiconductor layer structure 60, a width therebetween impacts the conduction path 78 of the MOSFET 1. Since during on-state operation the conduction paths 78 (i.e., the source-to-drain current) flow through these JFET gaps 24, the width of each JFET gap 24 has a direct impact on the on-state resistance of the MOSFET 1. In addition, a minimum width between the p-type trench shielding region 52 and the adjacent p-type support shield 50 also has a direct impact on the on-state resistance of the MOSFET 1. While embodiments of the present invention may not necessarily illustrate a JFET gap as corresponding to a minimum width between a p-type trench shielding region and an adjacent p-type support shield, it will be appreciated that the minimum width is also a parameter which impacts the on-state resistance of a MOSFET. The first direction X and the second direction Y may be parallel to the major surfaces of a semiconductor layer structure of the semiconductor device. For example, the second direction Y may be perpendicular to the first direction X. The third direction Z intersects the first direction X and the second direction Y and may be perpendicular to the major surfaces of a semiconductor layer structure of the semiconductor device.

While the provision of the trench shielding regions 52 in the gate trench power MOSFET 1 may provide increased protection for the gate oxide layers 82, the trench shielding regions 52 may increase the on-state resistance of the MOSFET 1, thereby increasing power dissipation. In particular, when standard (random) ion implantation processes are used to form the trench shielding regions 52, the width of the trench shielding regions 52 tends to increase with increasing depth in the semiconductor layer structure 60 as the deeper the implant the more opportunities for the implanted dopant ions to collide with atoms in the crystal lattice and be redirected laterally. This phenomenon is sometimes referred to as “blooming”. As shown in FIG. 2, the blooming phenomenon can result in the trench shielding regions 52 having sidewalls that angle outwardly with increasing depth in the semiconductor layer structure 60. The lateral expansion of the trench shielding regions 52 acts to decrease the widths of the JFET gaps 24, thereby forcing the current in the conduction paths 78 to flow through a narrowed region, which acts to increase the on-state resistance of the MOSFET 1. The distances between each trench shielding region 52 (or gate trench 80) and the support shields 50 adjacent thereto may therefore be set to meet a desired on-state resistance value. This, however, may require increasing the spacing between the trench shielding regions 52 and the support shields 50 in order to obtain a sufficiently large JFET gap 24, which disadvantageously increases the cell pitch of the power MOSFET 1.

In particular, the cell pitch of a MOSFET refers to the center-to-center distance between adjacent unit cells. When trench shielding regions are added to a gate trench power MOSFET, it may be necessary to increase the spacing between adjacent gate trenches 80 to make room for the trench shielding regions 52 and obtain a sufficiently large JFET gap 24, thereby increasing the cell pitch, which reduces the integration level of the MOSFET 1. Thus, while the provision of the trench shielding regions 52 in the gate trench power MOSFET 1 may provide increased protection for the gate oxide layers 82, it presents a trade-off between the cell pitch and on-state resistance of the MOSFET 1.

Pursuant to embodiments of the present invention, gate trench silicon carbide power MOSFETs (and other power semiconductor devices) are provided that have improved trench shielding region designs. For example, in some embodiments, the trench shielding regions may be shaped using channeled ion implantation techniques to allow the cell pitch and/or on-state resistance of the MOSFET to be reduced. Channeled ion implants may exhibit significantly less blooming than random (standard) ion implants that are not performed along channels in the semiconductor crystal lattice. Thus, the power MOSFETs according to embodiments of the present invention may exhibit reduced fabrication costs and/or improved performance.

In some embodiments of the present invention, gate trench silicon carbide based power MOSFETs (and other gate trench power semiconductor devices) are provided that include trench shielding regions having substantially vertical sidewalls or sidewalls that angle inwardly with increasing depth. As such, the JFET gaps in these devices may either remain substantially constant or actually increase with increasing depth. As a result, the unit cells of the power MOSFETs according to embodiments of the present invention may be packed together more tightly while providing the same or even improved on-state resistance performance.

Pursuant to still further embodiments of the present invention, gate trench silicon carbide based power MOSFETs (and other gate trench power semiconductor devices) are provided that include trench shielding regions which extend into the drift region to provide a super junction structure therein. The so-called super junction drift region may increase the blocking voltage of the power MOSFET while reducing the impact thereof on the on-state resistance. Moreover, the trench shielding regions may be formed by the processes discussed above so that the trench shielding regions have substantially vertical sidewalls or sidewalls that angle inwardly with increasing depth.

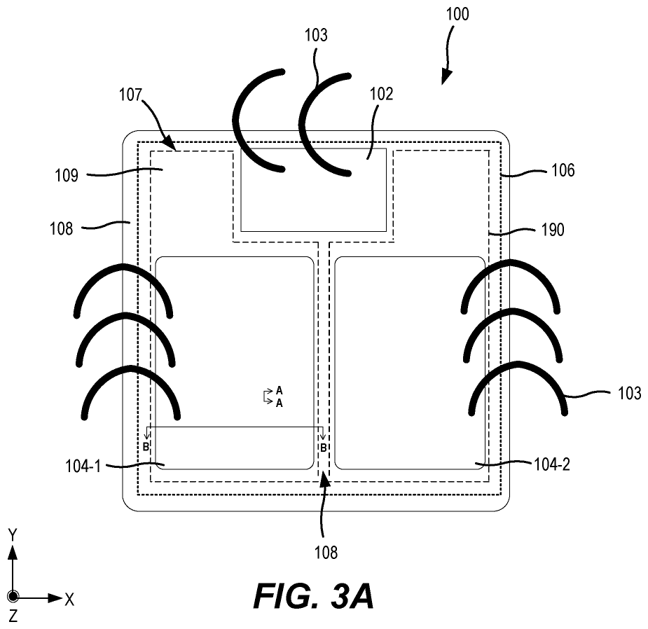

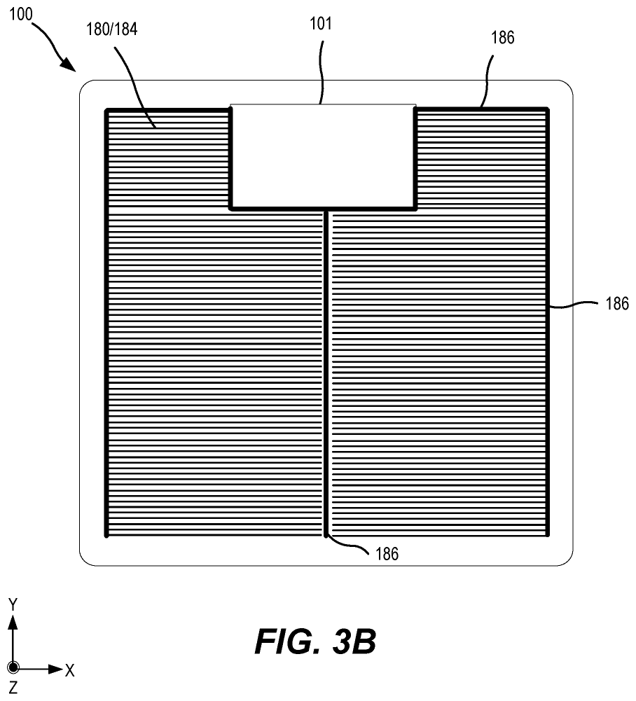

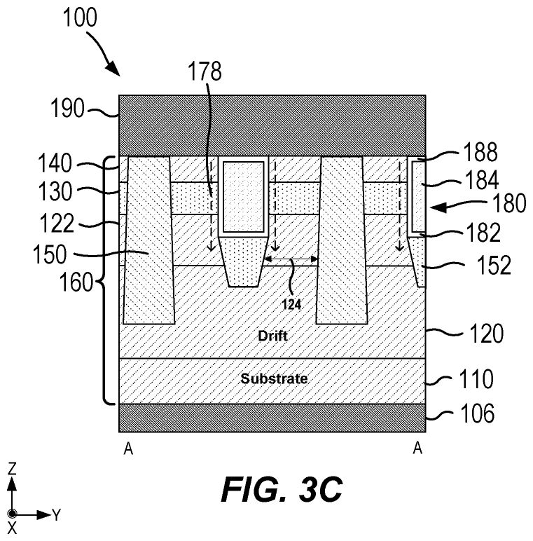

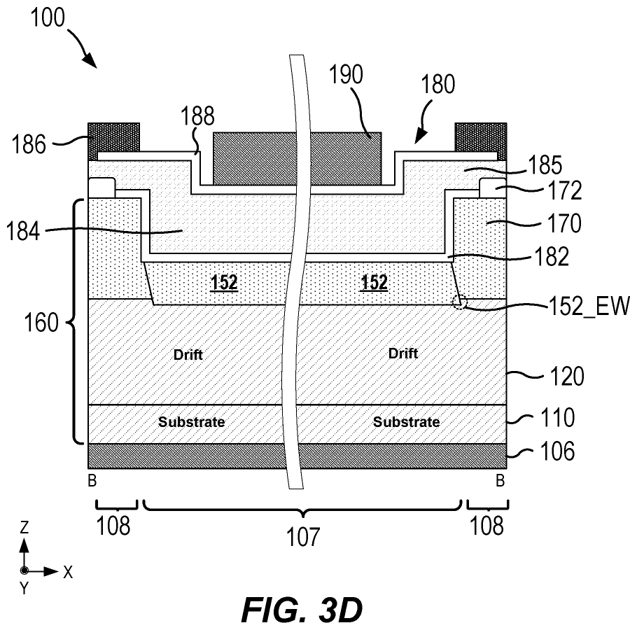

Embodiments of the present invention will now be described in more detail with reference to FIGS. 3A-16E. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top view of a gate trench silicon carbide power MOSFET 100 according to some embodiments of the present invention. FIG. 3B is a schematic plan view of the power MOSFET 100 with various top-side metal and dielectric layers thereof omitted to show the gate electrodes and gate buses. FIGS. 3C and 3D are schematic cross-sectional views of the gate trench silicon carbide power MOSFET 100 that are taken along lines A-A and B-B of FIG. 3A, respectively. It will be appreciated that the thicknesses of various of the layers and regions in FIGS. 3A-3D are not necessarily drawn to scale. The same is true with respect to the other figures included in this application.

The power MOSFET 100 includes a semiconductor layer structure 160 (sec FIGS. 3C and 3D) that comprises one or more semiconductor substrates and/or layers. At least one of the semiconductor layers in the semiconductor layer structure 160 may be a silicon carbide layer. Various metal and/or dielectric layers are formed on either side of the semiconductor layer structure 160 and embedded in the semiconductor layer structure 160.

As shown in FIG. 3A, the top-side metal layers include a gate bond pad 102 and one or more source bond pads 104-1, 104-2 that are formed on the upper side of the semiconductor layer structure 160. A metal drain pad 106 (shown as a dotted box in FIG. 3A) is provided on the bottom side of the semiconductor layer structure 160. The gate bond pad 102, the source bond pads 104-1, 104-2 and the drain pad 106 form the respective gate, source and drain terminals of the power MOSFET 100. The gate and source bond pads 102 and 104-1, 104-2 may each be formed of a metal, such as aluminum, that bond wires 103 can be readily attached to via conventional techniques such as thermo-compression or soldering. The drain pad 106 may likewise be a metal pad. A protective layer 109 such as a polyimide layer may cover the entire upper surface of the power MOSFET 100 except for the gate and source bond pads 102 and 104-1, 104-2.

Still referring to FIG. 3A, the power MOSFET 100 includes a source metallization layer 190 (indicated by the dashed boxes in FIG. 3A) that electrically connects certain regions of the semiconductor layer structure 160 to the source bond pads 104-1, 104-2. The source bond pads 104-1, 104-2 may be portions of the source metallization layer 190 that are exposed through openings in the protective layer 109 or may be separate metal layers. The source metallization layer 190 may generally overlie or correspond to an “active region” 107 of the power MOSFET 100 where the unit cell transistors are located. An inactive region 108 of the power MOSFET 100 surrounds the active region 107. The inactive region 108 may include a termination region that extends around the periphery of the MOSFET 100 that includes guard rings, junction termination elements or other termination structures, a gate pad region that underlies the gate bond pad 102, and gate bus regions (discussed below).

Bond wires 103 are shown in FIG. 3A that may be used to connect the gate bond pad 102 and the source bond pads 104-1, 104-2 to external circuits or the like. The drain pad 106 on the bottom side of the power MOSFET 100 may be connected to an external circuit through, for example, an underlying submount (not shown).

FIG. 3B is another plan view of the power MOSFET 100 with the gate and source bond pads 102 and 104-1, 104-2, the protective layer 109, the source metallization layer 190, intermetal dielectric layers 188 (see FIGS. 3C and 3D) and various other metal and dielectric layers removed to show gate electrodes 184 that are formed in gate trenches 180 in the semiconductor layer structure 160. A patterned field oxide layer 172 (see FIG. 3D) is formed on the semiconductor layer structure 160 in the inactive region 108 of the power MOSFET 100. The field oxide layer 172 may be a relatively thick oxide layer (e.g., ten to twenty times thicker than the gate oxide layers that are discussed below). A polysilicon layer 101 may be formed on the field oxide layer 172 and may be formed in the region where the gate bond pad 102 is formed so that the gate bond pad 102 vertically overlaps the field oxide layer 172 and the polysilicon layer 101. As used herein, two elements of a semiconductor device are considered to “vertically overlap” if an axis that is perpendicular to the major surfaces of a semiconductor layer structure of the semiconductor device intersects both elements.

One or more gate buses 186 are provided that extend around the periphery of the active region 107. The field oxide layer 172 typically runs underneath each gate bus 186 as well as underlying the gate bond pad 102. The gate buses 186 are electrically connected to the gate bond pad 102, often through gate resistors (not shown). A plurality of gate trenches 180 arc formed throughout the active region 107. A gate electrode 184 is formed in each gate trench 180. In the MOSFET 100, the gate electrodes 184 longitudinally extend in the first direction X across the semiconductor layer structure 160. In other cases, the gate electrodes 184 may longitudinally extend in the second direction Y across the semiconductor layer structure 160. Although not shown, gate electrodes 184 extending in the first direction X and the second direction Y can be provided to form a grid-like gate electrode structure. The gate electrodes 184 may be connected to the gate bond pad 102 through the gate buses 186. The gate electrodes 184 may comprise, for example, a doped polysilicon pattern. The gate buses 186 may comprise polysilicon and/or metal structures in example embodiments and typically are in the inactive region 108 of the power MOSFET 100.

FIG. 3C is a schematic cross-sectional view taken along line A-A of FIG. 3A that illustrates about one and a half unit cells of the power MOSFET 100. As shown in FIG. 3C, the power MOSFET 100 includes an n-type silicon carbide semiconductor substrate 110. The substrate 110 may comprise, for example, a single crystal 4H (or 6H) silicon carbide semiconductor substrate that is heavily-doped with n-type impurities. The impurities may include, for example, nitrogen or phosphorous. In example embodiments, the n-type substrate 110 may have a doping concentration of, for example, between 1×10¹⁸ and 1×10²¹ atoms/cm³, although other doping concentrations may be used. Herein, the “doping concentration” of a semiconductor material refers to the number of dopant atoms that cause the semiconductor material to have a certain conductivity type (i.e., cither n-type or p-type) that are present within a cubic centimeter of semiconductor material as measured using standard measurement techniques such as Secondary Ion Mass Spectrometry (“SIMS”). The doping concentration of a layer or region may be relatively constant or may vary (e.g., may be graded with depth), and the doping concentration refers to the peak doping concentration of the layer or region. For an n-type semiconductor material, references to the doping concentration refer to the concentration of n-type dopants, and for a p-type semiconductor material, references to the doping concentration refer to the concentration of p-type dopants.

The substrate 110 may be relatively thick in some embodiments (e.g., 20-100 microns or more). It should be noted that while the substrate 110 is depicted as a relatively thin layer, this is done to allow enlarging the thickness of other layers or regions in FIG. 3C, and it will be appreciated that the substrate 110 will typically be much thicker than shown. The thickness of various other layers or regions of the power MOSFET 100 likewise may not be shown to scale in order to allow other portions of the devices to be enlarged in the figures.

A lightly-doped n-type silicon carbide drift region 120 (which may also be referred to herein as a drift layer 120) is provided on an upper surface of the substrate 110. Typically, the drift region 120 is formed via an epitaxial growth process and is doped during growth. The n-type drift region 120 may have, for example, a doping concentration of 5×10¹⁵ to 5×10¹⁷ atoms/cm³. The drift region 120 may be a thick region, having a vertical height above the substrate 110 of, for example, 3-50 microns, and can be doped during growth. An upper portion of the drift region 120 may include n-type JFET regions 122. In some embodiments, the n-type JFET regions 122 may be more heavily doped than the remainder of the n-type drift region 120. In some other embodiments, the n-type JFET regions 122 may have a same doping concentration as the remainder of the n-type drift region 120. The JFET regions 122 may have an n-type dopant concentration of, for example, 5×10¹⁶ to 1×10¹⁸ atoms/cm³. For illustrative purposes, the JFET regions 122 are shown on the drift region 120. However, it will be understood that the JFET regions 122 can be considered on or in an upper portion of the drift region 120 and thus may be considered as part of the drift region 120.

The drift region 120 and the substrate 110 together act as a common drain region for the power MOSFET 100. The drain pad 106 is formed on the substrate 110 opposite the drift region 120.

Still referring to FIG. 3C, moderately-doped p-type silicon carbide well regions 130 (which may also be referred to herein as well layers 130 or p-wells 130) are formed on an upper portion of the n-type drift region 120 (i.e., on the n-type JFET regions 122). The silicon carbide well regions 130 may be formed either by epitaxial growth or by implanting p-type dopant ions into the upper portion of the n-type drift region 120 (i.e., into the n-type JFET regions 122) to convert the upper portion of the n-type drift region 120 into the p-type well regions 130. In example embodiments, the well regions 130 may have a p-type dopant concentration of, for example, between 5×10¹⁶ to 1×10¹⁸ atoms/cm³.

Heavily-doped n-type silicon carbide source regions 140 (which may also be referred to herein as source layers 140) are formed on the p-type silicon carbide well regions 130. The n-type silicon carbide source regions 140 may be formed by ion implantation. The n-type source regions 140 may have a doping concentration of, for example, between 1×10¹⁹ and 5×10²¹ atoms/cm³.

As is further shown in FIG. 3C, p-type silicon carbide support shields 150 are provided that extend downwardly from the upper portion (e.g., the upper surface) of the semiconductor layer structure 160 into the drift region 120. The p-type support shields 150 may be moderately or heavily doped silicon carbide regions. For example, each p-type support shield 150 may have a doping concentration between about 5×10¹⁶ and 1×10²² atoms/cm³. In other embodiments, each p-type support shield 150 may have a doping concentration between about 1×10¹⁸ and 1×10²⁰, between about 1×10¹⁹ and 1×10²⁰, between about 1×10¹⁷ and 1×10¹⁹, between about 1×10¹⁷ and 1×10²⁰, or between about 1×10¹⁸ and 1×10²¹ atoms/cm³. The p-type support shields 150 may have a doping concentration that is graded with depth. In example embodiments, each p-type support shield 150 may extend to a depth of between 0.1 microns and 4.0 microns from the upper surface of the semiconductor layer structure 160. In other embodiments, the depth of each p-type support shield 150 may be between 1.0 and 3.0 microns, between 1.0 and 2.5 microns, between 1.5 and 3.0 microns, between 1.5 and 2.5 microns, or between 0.5 and 2.5 microns. Any of the above dopant concentration ranges for the p-type support shields 150 may be matched with any of the above-listed depths for the p-type support shields 150. The p-type support shields 150 may act to reduce the electric field levels that form in gate oxide layers 182 during reverse blocking operation, as will be discussed in greater detail below.

Gate trenches 180 are formed in an upper portion of the semiconductor layer structure 160. As shown in FIG. 3C, p-type silicon carbide trench shielding regions 152 are formed underneath the respective gate trenches 180 and extend underneath the respective gate trenches 180 for all or substantially all of the length of the gate trenches 180 (e.g., in the first direction X). The p-type trench shielding regions 152 may be moderately or heavily doped silicon carbide regions. For example, each p-type trench shielding region 152 may have a doping concentration between about 1×10¹⁶ and 1×10²² atoms/cm³. In other embodiments, each p-type trench shielding region 152 may have a doping concentration between about 1×10¹⁸ and 1×10²⁰, between about 1×10¹⁹ and 1×10²⁰, between about 1×10¹⁷ and 1×10¹⁹, between about 1×10¹⁷ and 1×10²⁰, or between about 1×10¹⁸ and 1×10²¹ atoms/cm³. In example embodiments, each p-type trench shielding region 152 may extend to a depth of between 0.5 and 3.0 microns from a bottom surface of each gate trench 180 into the semiconductor layer structure 160. In other embodiments, the depth of each p-type trench shielding region 152 may be between 1.0 and 3.0 microns, between 1.0 and 2.5 microns, between 1.5 and 3.0 microns, between 1.5 and 2.5 microns, or between 0.5 and 2.5 microns. Any of the above dopant concentrations may be matched with any of the above-listed depths for the p-type trench shielding regions 152. The p-type trench shielding regions 152 act to reduce the electric field levels that form in gate oxide layers 182 during reverse blocking operation, as will be discussed in greater detail below. The p-type trench shielding regions 152 may be doped to have a higher p-type dopant concentration, a lower p-type dopant concentration, or approximately the same p-type dopant concentration as the p-type support shields 150.

While not shown in FIG. 3C, electrical connections may be provided, in and/or outside of the active region 107, that electrically connect the p-type trench shielding regions 152 to the p-type well regions 130. U.S. Pat. Nos. 9,887,287 and 11,610,991 each illustrate designs for metal or p-type silicon carbide trench shield connection patterns that can be used to electrically connect p-type trench shielding regions to p-type well regions. Any of the p-type silicon carbide trench shield connection patterns disclosed in these patents (each of which is incorporated herein by reference) can be used to electrically connect the p-type trench shielding regions 152 to the p-type well regions 130. Additionally or alternatively, the p-type trench shielding regions 152 may be directly connected to the source metallization layer 190 through p-type silicon carbide trench shield connection patterns that, for example, are formed in the gate trenches 180, as shown in U.S. Patent Publication No. 2022/0130998, the entire content of which is also incorporated herein by reference in its entirety.

The n-type silicon carbide substrate 110, the n-type silicon carbide drift region 120, the n-type silicon carbide JFET regions 122, the p-type silicon carbide well regions 130, the n-type silicon carbide source regions 140, the p-type silicon carbide support shields 150 and the p-type silicon carbide trench shielding regions 152 may together provide the semiconductor layer structure 160 of the power MOSFET 100.

As noted above, the plurality of gate trenches 180 are formed in the upper portion of the semiconductor layer structure 160. While only one full gate trench 180 and a portion of a second gate trench 180 are shown in the cross-section of FIG. 3C, it will be appreciated from FIG. 3B that the MOSFET 100 may include a large number of gate trenches 180. Each gate trench 180 may extend along a longitudinal axis through the semiconductor layer structure 160 (e.g., in the first direction X), and the gate trenches 180 may extend parallel to each other as shown best in FIG. 3B. It will be appreciated that the longitudinal axes of the gate trenches 180 extend into the page in the cross-section of FIG. 3C. The gate trenches 180 may be formed via an etching process.

A gate oxide layer 182 is provided in each gate trench 180 to cover the sidewalls and bottom surface of the gate trench 180. In some embodiments, each gate oxide layer 182 may extend onto the upper surface of the semiconductor layer structure 160. Each gate oxide layer 182 may comprise, for example, a silicon oxide (SiO₂) pattern, but is not limited thereto. The gate oxide layers 182 may or may not be connected to each other outside the view of FIG. 3C. The gate oxide layers 182 may be formed generally conformally within the respective gate trenches 180.

A gate electrode 184 is formed in each gate trench 180 on the gate oxide layer 182. The gate electrodes 184 may comprise conductive material such as a silicide (e.g., NiSi, TiSi, WSi, CoSi), doped polycrystalline silicon (poly-Si), and/or a stable conductor. Other suitable materials for the gate electrode 184 include various metals such as Ti, Ta or W or metal nitrides such as TIN, TaN or WN. The gate oxide layers 182 may insulate the gate electrodes 184 from the semiconductor layer structure 160, thereby preventing the gate electrodes 184 from short circuiting to the semiconductor layer structure 160. Each gate electrode 184 may connect to one of the gate buses 186 (see FIG. 3B). In FIG. 3C, the gate electrodes 184 are recessed so that the upper surface of each gate electrode 184 is below an upper surface of the semiconductor layer structure 160. It will be appreciated that in other embodiments, the gate electrodes 184 may extend above and onto the upper surface of the semiconductor layer structure 160, with the gate oxide layer 182 insulating the gate electrodes 184 from the upper surface of the semiconductor layer structure 160.

Intermetal dielectric layers 188 are formed that cover each gate electrode 184. The intermetal dielectric layers 188 insulate the source metallization layer 190 from the gate electrodes 184. The source metallization layer 190 is formed on the upper surface of the semiconductor layer structure 160 and on the intermetal dielectric layers 188. Herein, the source metallization layer 190 may also be referred to as the “source contact”. The source metallization layer 190 may include a single metal layer or multiple metal layers. Typically, multiple metal layers are provided, as the source metallization layer 190 may include a single layer or multi-layer adhesion layer that contacts the semiconductor layer structure 160, one or more barrier layers, and a bulk metal layer (e.g., an aluminum layer).

In example embodiments of the present invention, the p-type trench shielding regions 152 may be formed by channeled ion implantation techniques. When standard ion implantation techniques (which may also be referred to herein as random ion implantation techniques or non-channeled ion implantation techniques) are used, dopant ions are implanted at high energy into an upper surface of a semiconductor layer structure. As the dopant ions pass into the semiconductor material, they collide with atoms in the crystal lattice, which causes the dopant ions to lose energy and which may also redirect the dopant ions in different directions. Most typically, the dopant ions are implanted at an angle of 90° with respect to the upper surface of the semiconductor layer structure (i.e., vertically). As the dopant ions collide with atoms in the crystal lattice, they will be redirected so that they move both laterally and vertically through the crystal lattice. This lateral movement results in the implanted region spreading out laterally (the “blooming” phenomenon discussed above), and the amount of lateral spread tends to increase with increasing depth in the semiconductor layer structure. This can be seen in the cross-section of FIG. 2, where the sidewalls of the trench shielding region 52 angle outwardly with increasing depth in the semiconductor layer structure 60. As discussed above with reference to FIG. 2, this phenomenon acts to narrow the JFET gap 24, which may increase the on-state resistance of the MOSFET 1.

In contrast, as shown in FIG. 3C, each of the trench shielding regions 152 included in the MOSFET 100 have sidewalls that angle inwardly with increasing depth in the semiconductor layer structure 160, and thus the cross-sectional area of each trench shielding region 152 (taken along horizontal cross-sections of the trench shielding regions 152) decreases as the trench shielding region 152 extends farther in (from the upper surface of) the semiconductor layer structure 160. As a result, a JFET gap 124 does not narrow with increasing depth in the semiconductor layer structure 160 but instead remains substantially constant or actually widens. This may act to lower the on-state resistance of the power MOSFET 100. As will be discussed in greater detail below, trench shielding regions 152 having the shapes shown in FIG. 3C may be provided by forming the trench shielding regions 152 using a channeled ion implantation process.

The power MOSFET 100 may be turned on by applying a gate bias voltage that is above a threshold level to the gate pad 102 (see FIG. 3A). The gate bias voltage is transferred to the gate electrodes 184 via the gate buses 186 (see FIG. 3B) and creates conductive n-type inversion layers in portions of the p-type well regions 130 that are adjacent the gate trenches 180. These portions of the p-type well regions 130 are referred to herein as channel regions because channels or conduction paths 178 (shown by dashed arrows) of the MOSFET 100 provide a path for current to flow from the source regions 140 to the drift region 120 during on-state operation. The channel regions are vertically oriented (i.e., extend in the third direction Z), and the current in the conduction paths 178 flows downwardly from the source regions 140 through the channel region included in each well region 130 to the JFET regions 122, the drift region 120, the substrate 110 and the drain contact 106.

As discussed above, one common failure mechanism in power semiconductor devices such as power MOSFETs is device failure due to breakdown of the gate oxide layer. Since the lifetime (i.e., time until breakdown) of a gate oxide layer is a function of the intensity of the electric field in the gate oxide layer during device operation, one way to reduce the instances of device failure is to design the MOSFET to have reduced peak electric field values in the gate oxide layer during reverse blocking operation.

During reverse blocking operation, the electric field extends upwardly from the bottom of the MOSFET 100. As such, strong electric fields may extend upwardly toward the lower portion of the gate oxide layers 182. The p-type support shields 150 and the p-type trench shielding regions 152 act as a shield that reduces the electric field values. The support shields 150 help reduce electric fields that extend upwardly on both sides of each trench shielding region 152, and the trench shielding regions 152 help reduce the electric field levels directly underneath the gate trenches 180 where the gate oxide layers 182 may be most susceptible to breakdown.

JFET gaps may be set by the on-state resistance requirements for power MOSFETs. This parameter directly effects the integration level of the MOSFET, as the wider the JFET gap needs to be to meet the on-state resistance requirements, the larger the size of each unit cell of the MOSFET. As shown in FIG. 3C, since each trench shielding region 152 has sidewalls that angle inwardly with increasing distance from the gate trenches 180 in the third direction Z, the JFET gaps 124 are wider than the JFET gaps 24 described above with reference to FIG. 2. This widening of the JFET gaps 124 occurs without having to increase the distances between the trench shielding regions 152 (or gate trenches 180) and the support shields 150 adjacent thereto. The JFET gaps 124 may thus be wider than that needed to meet the on-state resistance requirements for the power MOSFET 100. This allows for higher integration in the MOSFET 100 without increasing the on-state resistance thereof, which reduces fabrication costs and the size of the MOSFET 100.

Still referring to FIG. 3C, it can be seen that the trench shielding region 152 extends underneath the gate trench 180, and the trench shielding region 152 has the sidewalls that angle inwardly with increasing depth in the semiconductor layer structure 160. In other words, the sidewalls of the trench shielding region 152 angle inwardly with increasing distance from the gate trench 180. As a result, a width of the trench shielding region 152 in the second direction Y decreases with increasing distance from the gate trench 180. The trench shielding region 152 may longitudinally extend underneath the gate trench 180 in the first direction X (i.e., into the page in FIG. 3C). It will be appreciated that, as used herein, references to the “depth” of structures or elements within the semiconductor layer structure 160 refer to the distance that those structures or elements are from the upper surface of the semiconductor layer structure 160 in the third direction Z, where the upper surface of the semiconductor layer structure 160 is the surface opposite the substrate 110 and is also the surface in which the gate trenches 180 arc formed.

As shown in FIG. 3C, the sidewalls of the trench shielding region 152 angle inwardly with increasing distance from the gate trench 180 in a direction perpendicular to a lower surface of the semiconductor layer structure 160 (i.e., the third direction Z). The sidewalls of the trench shielding region 152 may longitudinally extend in the first direction X (i.e., into the page in FIG. 3C) and oppose each other in the second direction Y. An average width in the second direction Y of an upper half of the trench shielding region 152 may be greater than an average width in the second direction Y of a lower half of the trench shielding region 152. The upper half of the trench shielding region 152 is between the gate trench 180 and the lower half of the trench shielding region 152. A maximum width of the trench shielding region 152 in the second direction Y may be less than or equal to a maximum width of the gate trench 180 in the second direction Y.

As discussed above, the semiconductor layer structure 160 includes, among other things, the p-type support shields 150. The support shields 150 may longitudinally extend in the first direction X (i.e., into the page in FIG. 3C) on opposite sides of each gate trench 180. As shown in FIG. 3C, two of the p-type support shields 150 may extend on first and second sides of one of the gate trenches 180, respectively. The first and second sides of the gate trench 180 oppose each other in the second direction Y. A portion of the n-type drift region 120 may be between one of the p-type support shields 150 and one of the p-type trench shielding regions 152. In some embodiments, the portion of the drift region 120 may have a width in the second direction Y that increases with increasing depth in the semiconductor layer structure 160 since the sidewalls of the trench shielding region 152 are angled inwardly. In some other embodiments, depending on the shape of the support shields 150, the portion of the drift region 120 may have a width in the second direction Y that is substantially constant with increasing depth in the semiconductor layer structure 160.

As shown in FIG. 3C, the support shields 150 have respective widths in the second direction Y that increase with increasing depth in the semiconductor layer structure 160. As will be discussed in greater detail below, in some embodiments, the support shields 150 may be formed by a random ion implantation process, which can result in the support shields 150 having the shapes shown in FIG. 3C.

As discussed above, the MOSFET 100 includes the gate oxide layer 182 and the gate electrode 184 that are in the gate trench 180. The semiconductor layer structure 160 includes the p-type well regions 130 on the n-type drift region 120, and the n-type source regions 140 on the p-type well regions 130. The semiconductor layer structure 160 may further include the n-type JFET regions 122, which may comprise at least part of an upper portion of the drift region 120. In some embodiments, the JFET regions 122 may have a higher first conductivity type (n) doping concentration than the drift region 120. In some other embodiments, the JFET regions 122 may have a same first conductivity type (n) doping concentration as the drift region 120. The well regions 130 may be on upper surfaces of the JFET regions 122. As shown in FIG. 3C, a portion of a JFET region 122 that is between one of the trench shielding regions 152 and one of the support shields 150 may have a width in the second direction Y that increases with increasing distance from a well region 130 since the sidewalls of the trench shielding region 152 are angled inwardly. The trench shielding regions 152 may extend into the JFET regions 122 and the drift region 120. Each trench shielding region 152 may include an upper portion that horizontally overlaps the JFET regions 122 and a lower portion that horizontally overlaps the drift region 120. The upper portion of each trench shielding region 152 may have a width in the second direction Y that is greater than a width of the lower portion of each trench shielding region 152 in the second direction Y.

Referring to FIG. 3D, it can be seen that the trench shielding region 152 has endwalls that are oblique with respect to a lower surface of the semiconductor layer structure 160. In other words, the endwalls of the trench shielding region 152 are neither parallel with nor perpendicular to the lower surface of the semiconductor layer structure 160. It will be appreciated that the cross-section of FIG. 3D is taken along the longitudinal axes of the gate trench 180, the gate electrode 184, and the trench shielding region 152. It will also be appreciated that the cross-section of FIG. 3D does not show an entirety of these longitudinal axes and instead omits a central portion thereof for ease of illustration (represented by the vertical squiggly line in FIG. 3D). The endwalls of the trench shielding region 152 oppose each other in the first direction X and may be adjacent the inactive region 108 of the power MOSFET 100. Unlike the sidewalls of the trench shielding region 152 shown in FIG. 3C, the endwalls of the trench shielding region 152 may extend substantially parallel to each other, as shown in FIG. 3D. That is, the endwalls of the trench shielding region 152 may be slanted in a same direction with increasing distance from the bottom of the gate trench 180. The endwalls of the trench shielding region 152 may longitudinally extend in the second direction Y (i.e., into the page in FIG. 3D).

The inactive region 108 of the power MOSFET 100 may include the gate bus 186, the field oxide layer 172, and a heavily-doped silicon carbide p-type region 170. The p-type region 170 may be formed in an upper portion of the n-type drift region 120 by, for example, ion implantation. The p-type region 170 may be formed underneath the gate bus 186 and the field oxide layer 172. The p-type region 170 forms part of the semiconductor layer structure 160.

At the end of the gate trench 180, a gate electrode extension 185 may protrude out of the gate trench 180 and laterally extend across the semiconductor layer structure 160. The gate oxide layer 182 and/or the field oxide layer 172 may separate each gate electrode extension 185 from the semiconductor layer structure 160. The gate bus 186 may be formed on the gate electrode extension 185 to provide the electrical connection between the gate electrode 184 and the gate bus 186.

As shown in FIG. 3D, the trench shielding region 152 and the gate trench 180 extend in the active region 107 of the power MOSFET 100, and the endwalls of the trench shielding region 152 and the gate trench 180 may abut the p-type region 170. One of the endwalls of the trench shielding region 152 (e.g., on the right-hand side of FIG. 3D) may extend past one of the endwalls of the gate trench 180 in the first direction X toward the inactive region 108. The one of the endwalls of the trench shielding region 152 may include a portion 152_EW (shown by dotted circle) that is free of vertical overlap with the gate trench 180. For example, the portion 152_EW may be a lower portion of the one of the endwalls of the trench shielding region 152. The endwalls of the trench shielding region 152 may extend along a crystallographic axis of the semiconductor layer structure 160. In some embodiments, the crystallographic axis is one of the <11-23>, <−1-123>, <1-213>, <−12-13>, <2-1-13> or <−2113> crystallographic axes. In some other embodiments, the crystallographic axis is the <0001> crystallographic axis. As will be discussed in greater detail below, the trench shielding region 152 having the shape shown in FIG. 3D may be provided by forming the trench shielding region 152 using a channeled ion implantation process.

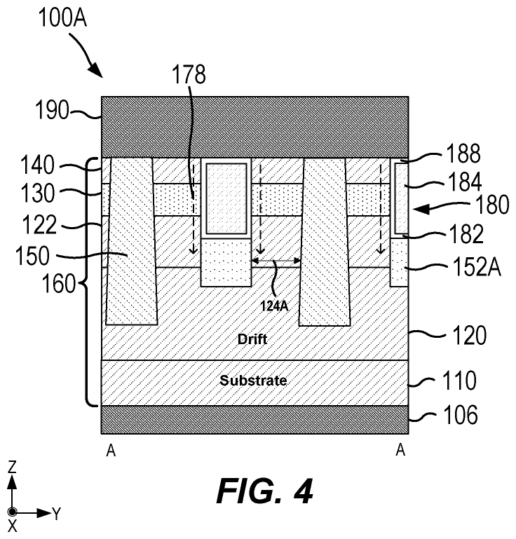

FIGS. 4-12B are schematic cross-sectional views of gate trench silicon carbide power MOSFETs 100A-1000, respectively, that are modified versions of the gate trench silicon carbide power MOSFET 100 of FIGS. 3A-3D, according to some embodiments of the present invention. The cross-sections of FIGS. 4-12B are taken along line A-A of FIG. 3A. Like reference numbers refer to like elements described above. MOSFETs 100A-1000 are similar to MOSFET 100, so the discussion of FIGS. 4-12B will focus on the differences therebetween.

Referring to FIG. 4, a power MOSFET 100A includes trench shielding regions 152A having sidewalls that are substantially vertical. That is, each trench shielding region 152A has sidewalls that extend substantially perpendicular to a lower surface of the semiconductor layer structure 160 with increasing distance from the gate trenches 180 in the third direction Z. As a result, a width of each trench shielding region 152A in the second direction Y may remain substantially constant with increasing distance from the gate trenches 180 in the third direction Z. An average width of an upper half of each trench shielding region 152A may be equal to an average width of a lower half of each trench shielding region 152A.

The cross-section of the MOSFET 100 shown in FIG. 3D is substantially identical to that of the MOSFET 100A, and thus the description of the trench shielding region 152 with reference to FIG. 3D also applies to the trench shielding region 152A.

Since each trench shielding region 152A has vertical sidewalls, JFET gaps 124A of the power MOSFET 100A may be wider than the JFET gaps 24 described above with reference to FIG. 2. This may act to lower the on-state resistance of the power MOSFET 100A. The trench shielding regions 152A may also allow for increased integration, which reduces fabrication costs and the size of the MOSFET 100A. As will be discussed in greater detail below, the trench shielding regions 152A having the shapes shown in FIG. 4 may be provided by forming the trench shielding regions 152A using a channeled ion implantation process.

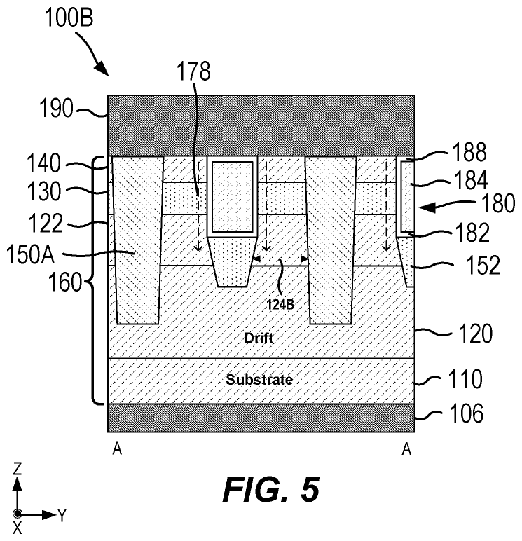

Referring to FIG. 5, a power MOSFET 100B includes p-type support shields 150A having respective widths in the second direction Y that decrease with increasing depth in the semiconductor layer structure 160. Although not shown, in some other embodiments, the p-type support shields 150A may have respective widths in the second direction Y that remain substantially constant with increasing depth in the semiconductor layer structure 160.

A portion of the n-type drift region 120 may be between one of the p-type support shields 150A and one of the p-type trench shielding regions 152. As shown in FIG. 5, the portion of the drift region 120 has a width in the second direction Y that increases with increasing depth in the semiconductor layer structure 160 since the sidewalls of the trench shielding region 152 and the sidewalls of the support shield 150A are both angled inwardly.

Since the p-type support shields 150A have respective widths in the second direction Y that decrease with increasing depth in the semiconductor layer structure 160, JFET gaps 124B of the power MOSFET 100B may be wider than the JFET gaps 24 described above with reference to FIG. 2. This may act to lower the on-state resistance of the power MOSFET 100B. The support shields 150A may also allow for increased integration, which reduces fabrication costs and the size of the MOSFET 100B. As will be discussed in greater detail below, the support shields 150A having the shapes shown in FIG. 5 may be provided by forming the support shields 150A using a channeled ion implantation process.

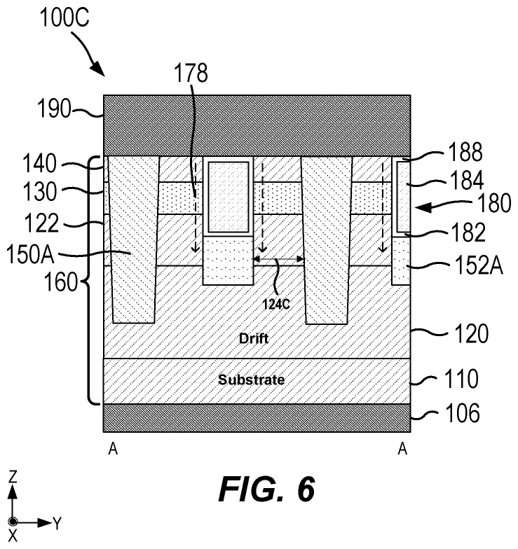

Referring to FIG. 6, a power MOSFET 100C includes the trench shielding regions 152A and the support shields 150A described above. As a result, JFET gaps 124C of the power MOSFET 100C may be wider than the JFET gaps 24 described above with reference to FIG. 2. This may act to lower the on-state resistance of the power MOSFET 100C.

A portion of the n-type drift region 120 may be between one of the p-type support shields 150A and one of the p-type trench shielding regions 152A. As shown in FIG. 6, the portion of the drift region 120 has a width in the second direction Y that increases with increasing depth in the semiconductor layer structure 160 since the sidewalls of the trench shielding region 152A are substantially vertical and the sidewalls of the support shield 150A are angled inwardly.

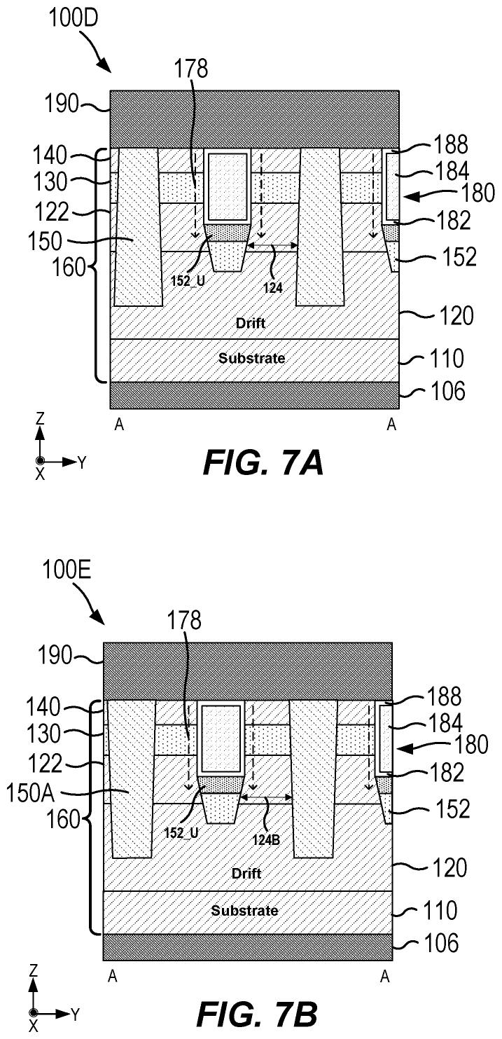

Referring to FIG. 7A, a power MOSFET 100D includes the trench shielding region 152, and the trench shielding region 152 includes an upper portion 152_U that is between the gate trench 180 and a lower portion of the trench shielding region 152. The upper portion 152_U of the trench shielding region 152 has a higher second conductivity type (p) doping concentration than the lower portion of the trench shielding region 152.

During reverse blocking operation, the bottom portion of the gate oxide layer 182 typically experiences the highest electric field levels. Due to electric field crowding effects, the electric field levels in the lower “corners” of the gate oxide layer 182 at the bottom edges of the gate trench 180 may be particularly high (i.e., the portions of the gate oxide layer 182 that cover the region where the sidewalls of the gate trench 180 merge into the bottom of the gate trench 180). The more heavily doped upper portion 152_U of the trench shielding region 152 may provide increased protection for the gate oxide layer 182 by reducing the electric field levels in areas where the gate oxide layer 182 is most susceptible to breakdown, thereby improving the lifetime of the gate oxide layer 182.

In some embodiments, a maximum width of the upper portion 152_U of the trench shielding region 152 in the second direction Y may be less than or equal to a maximum width of the gate trench 180 in the second direction Y. In some embodiments, the upper portion 152_U of the trench shielding region 152 may have sidewalls that angle inwardly with increasing distance from the gate trench 180 in the third direction Z.

In some other embodiments, the upper portion 152_U of the trench shielding region 152 may have sidewalls that are substantially vertical (i.e., substantially perpendicular to a lower surface of the semiconductor layer structure 160) or that angle slightly outward with increasing distance from the gate trench 180 in the third direction Z. This may result from the upper portion 152_U of the trench shielding region 152 being formed by a random ion implantation process. In this case, at least a portion (e.g., a lower half) of the trench shielding region 152 will have sidewalls that angle inwardly with increasing distance from the gate trench 180 in the third direction Z. The upper portion 152_U of the trench shielding region 152 may extend from a bottom surface of the gate trench 180 into an upper portion of the drift region 120 (i.e., into the JFET region 122). Since the upper portion 152_U of the trench shielding region 152 does not extend as deep in the semiconductor layer structure 160, the upper portion 152_U may exhibit significantly less blooming than that which may occur if an entirety of the trench shielding region 152 was formed by random ion implantation. As a result, there may be minimal to no impact on the JFET gaps 124.

Referring to FIG. 7B, a power MOSFET 100E includes the trench shielding region 152 that has the upper portion 152_U described above. The power MOSFET 100E also includes the p-type support shields 150A described above. For case of description, repeated descriptions of these elements are omitted.

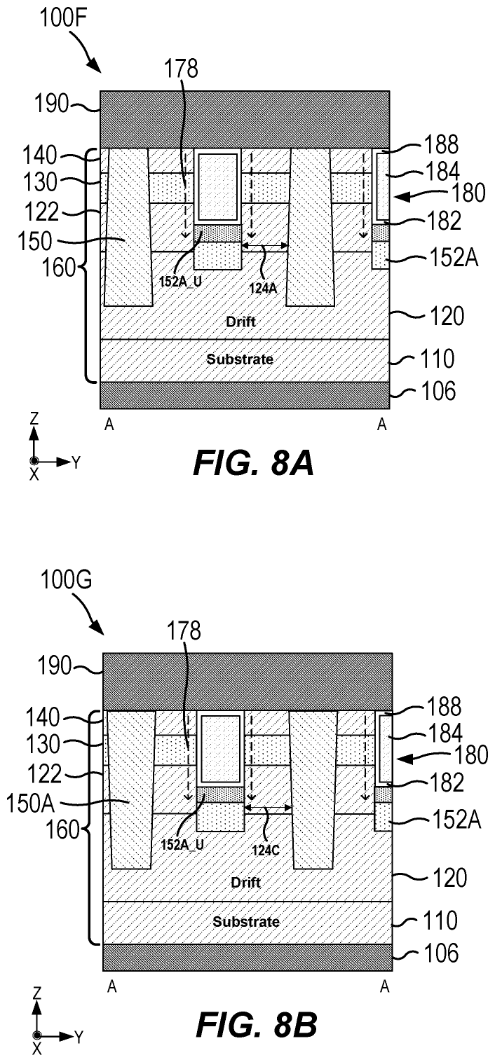

Referring to FIG. 8A, a power MOSFET 100F includes the trench shielding region 152A, and the trench shielding region 152A includes an upper portion 152A_U that is between the gate trench 180 and a lower portion of the trench shielding region 152A. The upper portion 152A_U of the trench shielding region 152A has a higher second conductivity type (p) doping concentration than the lower portion of the trench shielding region 152A.

As discussed above, during reverse blocking operation, the bottom portion of the gate oxide layer 182 typically experiences the highest electric field levels. The more heavily doped upper portion 152A_U of the trench shielding region 152A may provide increased protection for the gate oxide layer 182 by reducing the electric field levels in areas where the gate oxide layer 182 is most susceptible to breakdown, thereby improving the lifetime of the gate oxide layer 182.

In some embodiments, a maximum width of the upper portion 152A_U of the trench shielding region 152A in the second direction Y may be less than or equal to a maximum width of the gate trench 180 in the second direction Y. In some embodiments, the upper portion 152A_U of the trench shielding region 152A may have sidewalls that are substantially vertical (i.e., substantially perpendicular to a lower surface of the semiconductor layer structure 160) with increasing distance from the gate trench 180 in the third direction Z.

In some other embodiments, the upper portion 152A_U of the trench shielding region 152A may have sidewalls that angle slightly outward with increasing distance from the gate trench 180 in the third direction Z. This may result from the upper portion 152A_U of the trench shielding region 152A being formed by a random ion implantation process. In this case, at least a portion (e.g., a lower half) of the trench shielding region 152A will have sidewalls that are substantially vertical (i.e., substantially perpendicular to a lower surface of the semiconductor layer structure 160) with increasing distance from the gate trench 180 in the third direction Z. The upper portion 152A_U of the trench shielding region 152A may extend from a bottom surface of the gate trench 180 into an upper portion of the drift region 120 (i.e., into the JFET region 122). Since the upper portion 152A_U of the trench shielding region 152A does not extend as deep in the semiconductor layer structure 160, the upper portion 152A_U may exhibit significantly less blooming than that which may occur if an entirety of the trench shielding region 152A was formed by random ion implantation. As a result, there may be minimal to no impact on the JFET gaps 124A.

Referring to FIG. 8B, a power MOSFET 100G includes the trench shielding region 152A that has the upper portion 152A_U described above. The power MOSFET 100G also includes the p-type support shields 150A described above. For case of description, repeated descriptions of these elements are omitted.

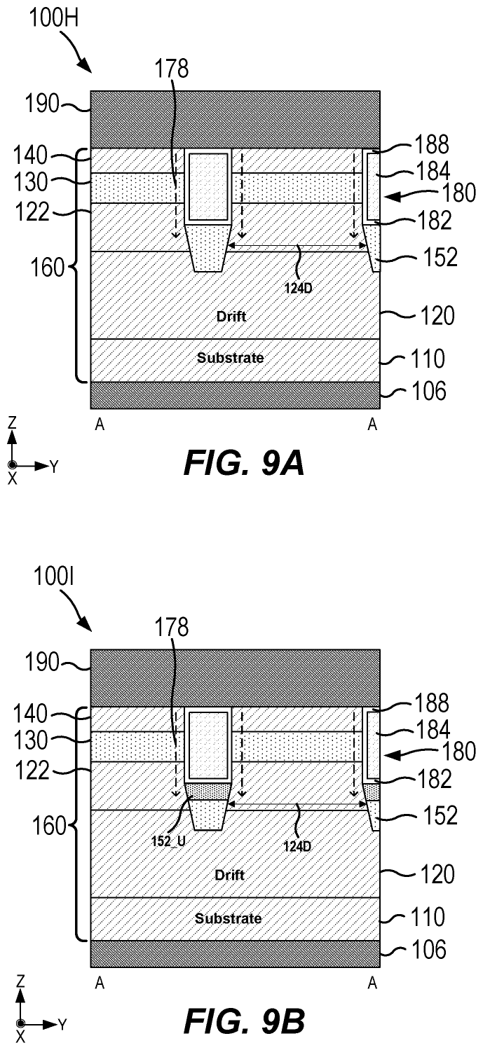

Referring to FIG. 9A, a power MOSFET 100H does not include the p-type support shields 150 or the p-type support shields 150A described above. As a result, JFET gaps 124D extend between the trench shielding regions 152 and are thus further widened. While the omission of the p-type support shields 150, 150A may lead to reduced protection of the gate oxide layer 182 during reverse blocking operation, the wider JFET gaps 124D may act to lower the on-state resistance of the power MOSFET 100H. The omission of the p-type support shields 150, 150A may also allow for increased integration, which reduces fabrication costs and the size of the MOSFET 100H.

Referring to FIG. 9B, a power MOSFET 100I does not include the p-type support shields 150 or the p-type support shields 150A described above. In addition, the power MOSFET 100I includes the trench shielding region 152 that has the more heavily doped upper portion 152_U described above. For ease of description, repeated descriptions of these elements are omitted.

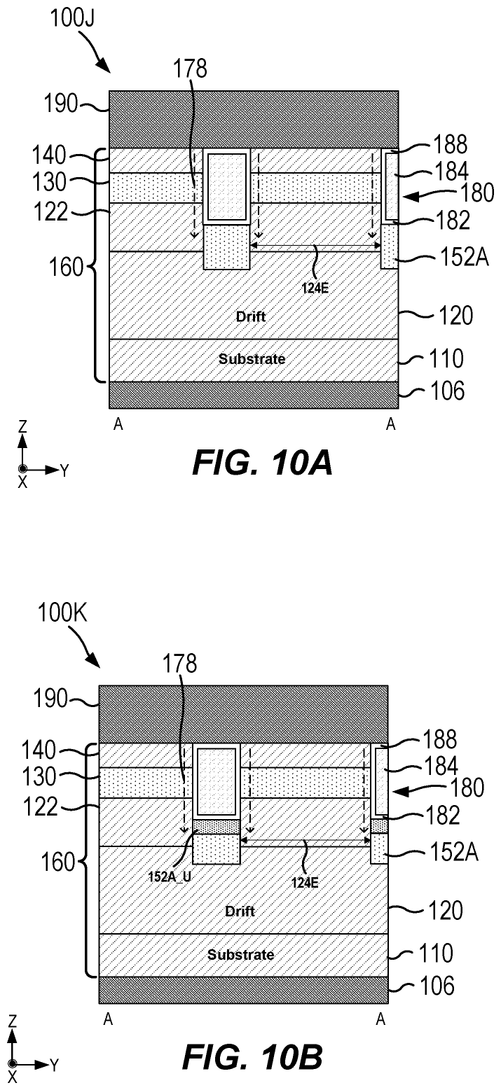

Referring to FIG. 10A, a power MOSFET 100J does not include the p-type support shields 150 or the p-type support shields 150A described above. As a result, JFET gaps 124E may extend between the trench shielding regions 152A and are thus further widened. While the omission of the p-type support shields 150, 150A may lead to reduced protection of the gate oxide layer 182 during reverse blocking operation, the wider JFET gaps 124E may act to lower the on-state resistance of the power MOSFET 100J. The omission of the p-type support shields 150, 150A may also allow for increased integration, which reduces fabrication costs and the size of the MOSFET 100J.

Referring to FIG. 10B, a power MOSFET 100K does not include the p-type support shields 150 or the p-type support shields 150A described above. In addition, the power MOSFET 100K includes the trench shielding region 152A that has the more heavily doped upper portion 152A_U described above. For case of description, repeated descriptions of these elements are omitted.

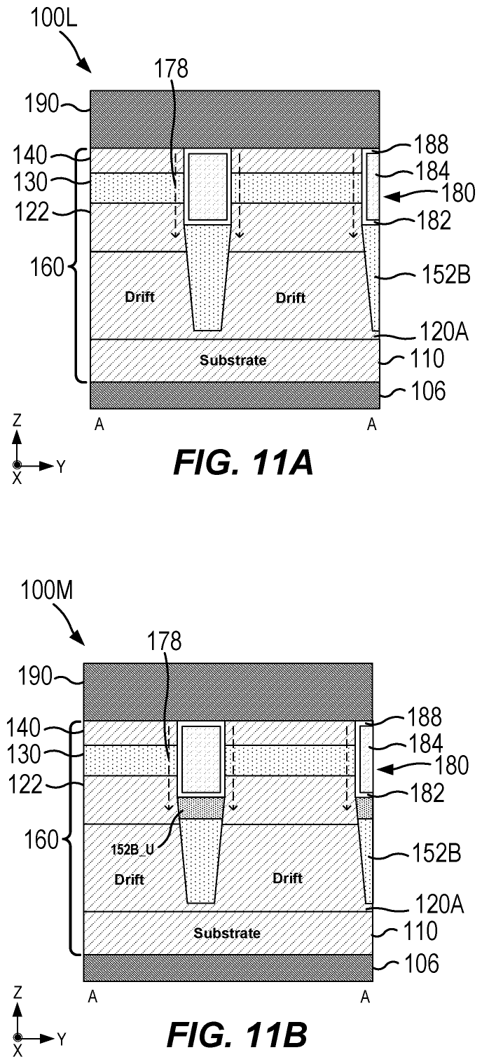

Referring to FIG. 11A, a power MOSFET 100L includes p-type trench shielding regions 152B and an n-type drift region 120A (which may also be referred to herein as a super junction drift region 120A). The power MOSFET 100L does not include the p-type support shields 150 or the p-type support shields 150A described above. The trench shielding regions 152B are similar to the trench shielding regions 152 described above but extend deeper into the drift region 120A to provide a super junction structure in the drift region 120A. The power MOSFET 100L may thus be referred to as a gate trench silicon carbide super junction power MOSFET 100L.

The so-called super junction drift region 120A may increase the blocking voltage of the power MOSFET 100L while reducing the impact thereof on the on-state resistance. In the drift region 120A having a super junction structure, the drift region 120A is divided by the trench shielding regions 152B into alternating, side-by-side n-type and p-type regions. The portions of the drift region 120A divided by the trench shielding regions 152B provide the n-type regions, and the trench shielding regions 152B provide the p-type regions. In some embodiments, the n-type drift region 120A and the p-type trench shielding regions 152B may be more heavily doped (e.g., doped 2× to 200× higher) than the drift region 120 and the p-type trench shielding regions 152, 152A described above, respectively. These side-by-side n-type and p-type regions are often referred to as “pillars.” The number of charge carriers in each n-type pillar (i.e., each portion of the drift region 120A) may be approximately equal to (e.g., within 20% or, more preferably, within 10% or within 5% or within 2%) the number of charge carriers in each p-type pillar (i.e., each trench shielding region 152B). The number of charge carriers in each pillar may be set by selecting the width and doping concentration of each pillar. When the number of charge carriers in adjacent n-type and p-type pillars are approximately equal, the interface between the pillars will laterally deplete during reverse blocking operation, which acts to change the shape of the electric field that forms in the drift region 120A during reverse blocking operation. In particular, the portion of the electric field that exceeds a first level may have a generally rectangular shape in the super junction style drift region 120A. The generally rectangular electric field that forms in the super junction style drift region 120A acts to better spread the electric field throughout the lower portion of the drift region 120A, which reduces the electric field values in upper portions of the semiconductor layer structure 160 where high electric field values can damage the gate oxide layers 182. Thus, the super junction style drift region 120A may exhibit superior performance during reverse blocking operation. Moreover, since the drift region 120A may be more heavily-doped, the resistance of the super junction style drift region 120A during on-state operation may be reduced.

In example embodiments of the present invention, the trench shielding regions 152B function both to provide the super junction structure in the drift region 120A and to shield the gate oxide layers 182 from high electric-fields during reverse blocking operation.

As shown in FIG. 11A, the trench shielding regions 152B have sidewalls that angle inwardly with increasing distance from the gate trenches 180 in the third direction Z. As a result, respective widths of the trench shielding regions 152B in the second direction Y decrease with increasing distance from the gate trenches 180. A distance between adjacent ones of the trench shielding regions 152B in the second direction Y may increase with increasing depth in the semiconductor layer structure 160. A portion of the n-type drift region 120A (i.e., an n-type pillar) between adjacent ones of the p-type trench shielding regions 152B may have a width in the second direction Y that increases with increasing depth in the semiconductor layer structure 160. An average width of an upper half of each trench shielding region 152B in the second direction Y may be greater than an average width of a lower half of each trench shielding region 152B in the second direction Y. As will be discussed in greater detail below, trench shielding regions 152B having the shapes shown in FIG. 11A may be provided by forming the trench shielding regions 152B using a channeled ion implantation process. The channeled ion implantation process may also allow the trench shielding regions 152B to extend deeper into the drift region 120A to block very high voltages during reverse blocking operation. For example, the trench shielding region 152B may extend from a bottom surface of the gate trench 180 into the JFET region 122 (i.e., into an upper portion of the drift region 120A) and the drift region 120A to a depth greater than or equal to 4 microns. The trench shielding region 152B may be aligned with the gate trench 180 for all or substantially all of the length of the gate trench 180 in the first direction X (i.e., into the page in FIG. 11A).

Referring to FIG. 11B, a power MOSFET 100M includes the trench shielding region 152B, and the trench shielding region 152B includes an upper portion 152B_U that is between the gate trench 180 and a lower portion of the trench shielding region 152B. The upper portion 152B_U of the trench shielding region 152B has a higher second conductivity type (p) doping concentration than the lower portion of the trench shielding region 152B.

As discussed above, during reverse blocking operation, the bottom portion of the gate oxide layer 182 typically experiences the highest electric field levels. The more heavily doped upper portion 152B_U of the trench shielding region 152B may provide increased protection for the gate oxide layer 182 by reducing the electric field levels in areas where the gate oxide layer 182 is most susceptible to breakdown, thereby improving the lifetime of the gate oxide layer 182.

In some embodiments, a maximum width of the upper portion 152B_U of the trench shielding region 152B in the second direction Y may be less than or equal to a maximum width of the gate trench 180 in the second direction Y. In some embodiments, the upper portion 152B_U of the trench shielding region 152B may have sidewalls that angle inwardly with increasing distance from the gate trench 180 in the third direction Z.

In some other embodiments, the upper portion 152B_U of the trench shielding region 152B may have sidewalls that are substantially vertical (i.e., substantially perpendicular to a lower surface of the semiconductor layer structure 160) or that angle slightly outward with increasing distance from the gate trench 180 in the third direction Z. This may result from the upper portion 152B_U of the trench shielding region 152B being formed by a random ion implantation process. In this case, at least a portion (e.g., a lower half) of the trench shielding region 152B will have sidewalls that angle inwardly with increasing distance from the gate trench 180 in the third direction Z. The upper portion 152B_U of the trench shielding region 152B may extend from a bottom surface of the gate trench 180 into the JFET region 122 (i.e., into an upper portion of the drift region 120A). Since the upper portion 152B_U of the trench shielding region 152B does not extend as deep in the semiconductor layer structure 160, the upper portion 152B_U may exhibit significantly less blooming than that which may occur if an entirety of the trench shielding region 152B was formed by random ion implantation.

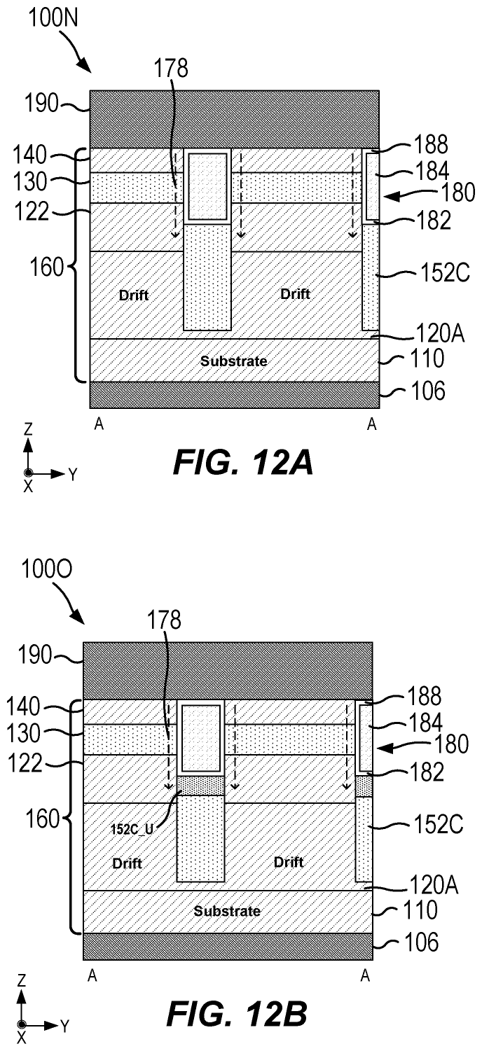

Referring to FIG. 12A, a power MOSFET 100N includes p-type trench shielding regions 152C and the n-type super junction drift region 120A. The trench shielding regions 152C are similar to the trench shielding regions 152B described above but have sidewalls that are substantially vertical (i.e., substantially perpendicular to the lower surface of the semiconductor layer structure 160) with increasing distance from the gate trenches 180 in the third direction Z. As a result, respective widths of the trench shielding regions 152C in the second direction Y may remain substantially constant with increasing distance from the gate trenches 180 in the third direction Z. As discussed above, the so-called super junction drift region 120A may increase the blocking voltage of the power MOSFET 100N while reducing the impact thereof on the on-state resistance.

As shown in FIG. 12A, a distance between adjacent ones of the trench shielding regions 152C in the second direction Y may be substantially constant with increasing depth in the semiconductor layer structure 160. An average width of an upper half of each trench shielding region 152C in the second direction Y may be equal to an average width of a lower half of each trench shielding region 152C in the second direction Y. As will be discussed in greater detail below, trench shielding regions 152C having the shapes shown in FIG. 12A may be provided by forming the trench shielding regions 152C using a channeled ion implantation process. The channeled ion implantation process may also allow the trench shielding regions 152C to extend deeper into the drift region 120A to block very high voltages during reverse blocking operation. For example, the trench shielding region 152C may extend from a bottom surface of the gate trench 180 into the JFET region 122 (i.e., into an upper portion of the drift region 120A) and the drift region 120A to a depth greater than or equal to 4 microns. The trench shielding region 152C may be aligned with the gate trench 180 for all or substantially all of the length of the gate trench 180 in the first direction X (i.e., into the page in FIG. 12A).

Referring to FIG. 12B, a power MOSFET 1000 includes the trench shielding region 152C, and the trench shielding region 152C includes an upper portion 152C_U that is between the gate trench 180 and a lower portion of the trench shielding region 152C. The upper portion 152C_U of the trench shielding region 152C has a higher second conductivity type (p) doping concentration than the lower portion of the trench shielding region 152C.

As discussed above, during reverse blocking operation, the bottom portion of the gate oxide layer 182 typically experiences the highest electric field levels. The more heavily doped upper portion 152C_U of the trench shielding region 152C may provide increased protection for the gate oxide layer 182 by reducing the electric field levels in areas where the gate oxide layer 182 is most susceptible to breakdown, thereby improving the lifetime of the gate oxide layer 182.

In some embodiments, a maximum width of the upper portion 152C_U of the trench shielding region 152C in the second direction Y may be less than or equal to a maximum width of the gate trench 180 in the second direction Y. In some embodiments, the upper portion 152C_U of the trench shielding region 152C may have sidewalls that are substantially vertical (i.e., substantially perpendicular to a lower surface of the semiconductor layer structure 160) with increasing distance from the gate trench 180 in the third direction Z.

In some other embodiments, the upper portion 152C_U of the trench shielding region 152C may have sidewalls that angle slightly outward with increasing distance from the gate trench 180 in the third direction Z. This may result from the upper portion 152C_U of the trench shielding region 152C being formed by a random ion implantation process. In this case, at least a portion (e.g., a lower half) of the trench shielding region 152C will have sidewalls that are substantially vertical (i.e., substantially perpendicular to a lower surface of the semiconductor layer structure 160) with increasing distance from the gate trench 180 in the third direction Z. The upper portion 152C_U of the trench shielding region 152C may extend from a bottom surface of the gate trench 180 into the JFET region 122 (i.e., into an upper portion of the drift region 120A). Since the upper portion 152C_U of the trench shielding region 152C does not extend as deep in the semiconductor layer structure 160, the upper portion 152C_U may exhibit significantly less blooming than that which may occur if an entirety of the trench shielding region 152C was formed by random ion implantation.

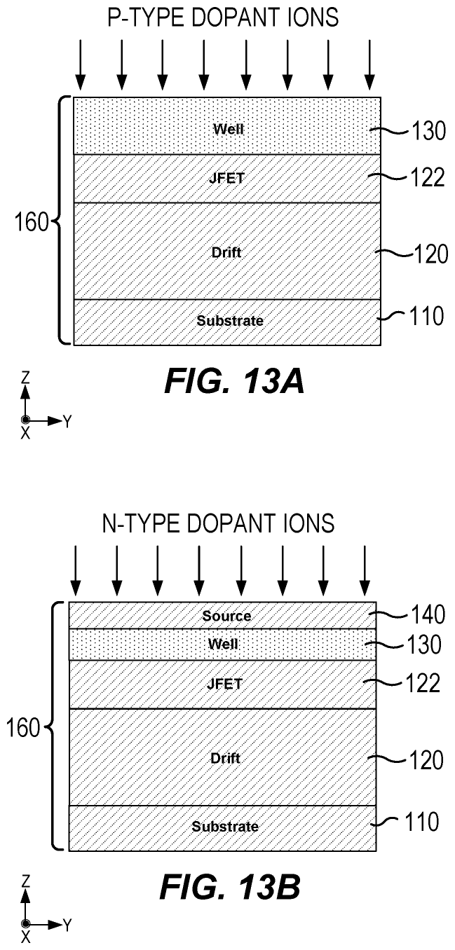

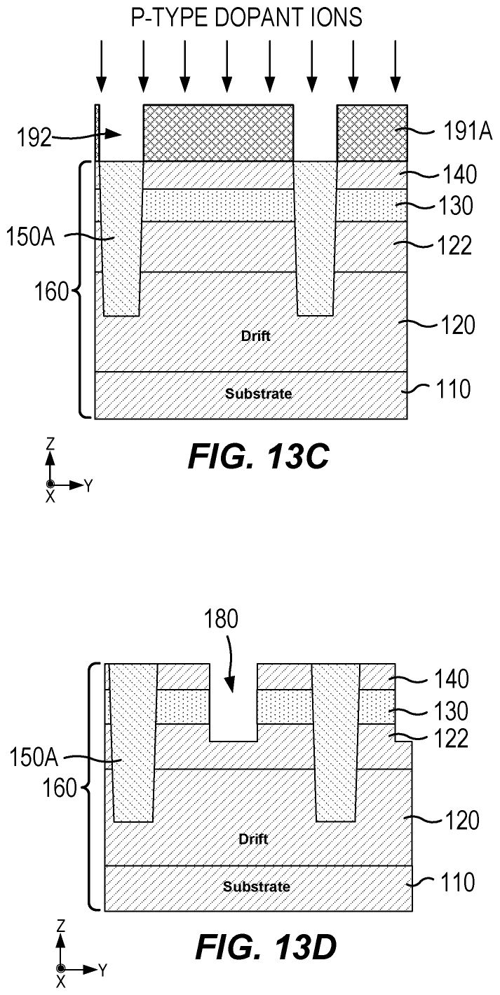

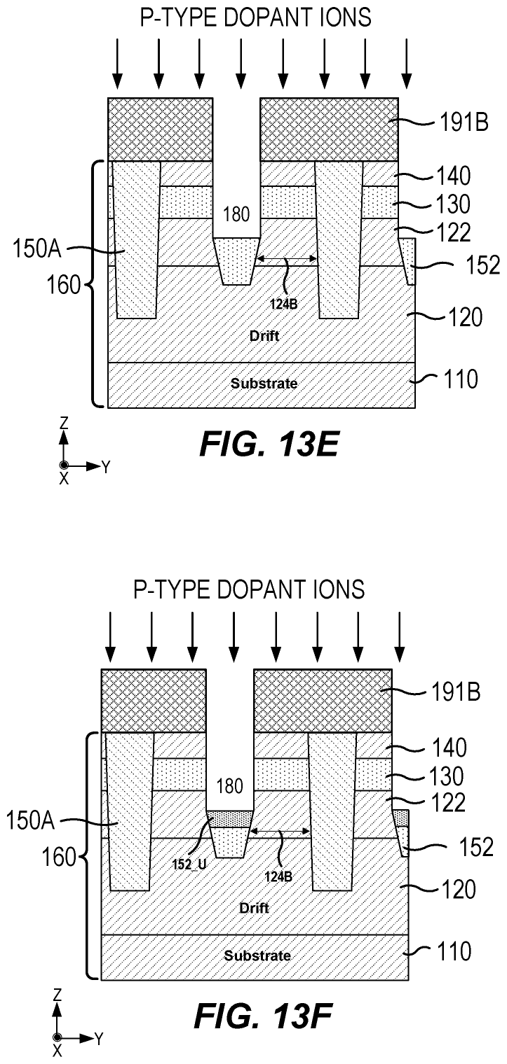

FIGS. 13A-13F are schematic cross-sectional views illustrating a method of fabricating a gate trench silicon carbide power MOSFET, according to some embodiments of the present invention. Like reference numbers in FIGS. 13A-13F refer to like elements described above.

Referring to FIG. 13A, the n-type silicon carbide substrate 110 is provided. The lightly-doped n-type silicon carbide drift region 120 is then formed on an upper surface of the substrate 110 by, for example, epitaxial growth. In some embodiments, the n-type dopant concentration may be increased during the growth of the upper portion of the drift region 120 to form the JFET region 122. In some other embodiments, the n-type dopant concentration may remain the same during the growth of the upper portion of the drift region 120 to form the JFET region 122. A moderately-doped p-type silicon carbide well region 130 (which may also be referred to as a well layer 130) is formed on the upper surface of the n-type drift region 120 (i.e., the upper surface of the JFET region 122), either by epitaxial growth or, more commonly, by implanting p-type dopant ions into the upper portion of the n-type drift region 120 (i.e., into the JFET region 122), as shown in FIG. 13A.

Referring to FIG. 13B, a heavily-doped silicon carbide source region 140 (which may also be referred to as a source layer 140) is formed in an upper portion of the p-type silicon carbide well region 130 by, for example, implanting n-type dopant ions into the upper portion of the well region 130. The silicon carbide substrate 110, drift region 120, JFET region 122, well region 130 and source region 140, along with various regions formed therein such as support shields and trench shielding regions (discussed below), comprise a semiconductor layer structure 160.

Referring to FIG. 13C, the moderately or heavily-doped silicon carbide support shields 150A are formed by implanting p-type dopant ions into the semiconductor layer structure 160. To form the support shields 150A, an ion implantation mask 191A is formed on the upper surface of the semiconductor layer structure 160. As shown in FIG. 13C, the ion implantation mask 191A is patterned to form openings 192 therein above the regions of the semiconductor layer structure 160 where the support shields 150A are to be formed. The support shields 150A are then formed by ion implantation, and the ion implantation mask 191A is removed thereafter. The support shields 150A may be formed by a channeled ion implantation process, which will be described in greater detail below with reference to FIG. 13E. Although not shown in FIG. 13C, in some other embodiments, the support shields 150 instead of the support shields 150A may be formed by implanting p-type dopant ions into the semiconductor layer structure 160. In this case, the support shields 150 may be formed by a random ion implantation process, which will be described in greater detail below with reference to FIG. 13F.

The support shields 150A may extend between 0.5 and 10 microns in the depth direction (i.e., the third direction Z) in the semiconductor layer structure 160. In some other embodiments, the support shields 150A may alternatively be formed prior to formation of the source region 140. The support shields 150A help reduce the electric field levels in gate oxide layers, which helps prevent premature breakdown of the gate oxide layers. The support shields 150A may also provide a low-resistance current path between the source and drain terminals of the MOSFET if the MOSFET experiences avalanche breakdown. This lower resistance current path helps reduce the amount that the device heats up during an avalanche breakdown event, increasing the likelihood that the MOSFET can survive such an event without damage.

Referring to FIG. 13D, an etching process may be carried out to form the plurality of gate trenches 180 in the upper portion of the semiconductor layer structure 160. Each gate trench 180 may extend laterally (i.e., parallel to a major surface of the semiconductor layer structure 160) in the first direction X (i.e., into the page in FIG. 13D) across the length (or width) of the power MOSFET. The gate trenches 180 may extend vertically in the third direction Z through the source region 140 and the well region 130, and into the JFET region 122 (i.e., into an upper portion of the drift region 120), as shown in FIG. 13D, and the gate trenches 180 may be spaced apart from each other in the second direction Y. For example, the formation of the gate trenches 180 may convert the well region 130 and the source region 140 into the plurality of well regions 130 and the plurality of source regions 140, respectively. The formation of the gate trenches 180 may also convert the JFET region 122 into the plurality of JFET regions 122.

Referring to FIG. 13E, the moderately or heavily-doped p-type silicon carbide trench shielding regions 152 are formed in the semiconductor layer structure 160 underneath each gate trench 180 by implanting p-type dopant ions into the semiconductor layer structure 160. As shown in FIG. 13E, an ion implantation mask 191B is formed on the upper surface of the semiconductor layer structure 160 and is patterned to form openings therein above the gate trenches 180. The trench shielding regions 152 are then formed by implanting the p-type dopant ions into the gate trenches 180. Although not shown, in some embodiments, spacers such as oxide spacers may be formed on the sidewalls of the gate trenches 180 before implanting the p-type dopant ions. The spacers may be formed by thermal oxidation of silicon carbide in portions of the semiconductor layer structure 160 surrounding the gate trench 180 or by depositing oxide into the gate trench 180 and then performing a blanket etch. The spacers may help prevent p-type ions from being implanted into the sidewalls of the gate trenches 180, which helps avoid the doping concentrations of regions in the semiconductor layer structure 160 adjacent the gate trenches 180 from being disadvantageously changed. For example, if portions of the JFET regions 122 adjacent the sidewalls of the gate trenches 180 are converted from n-type conductivity to p-type conductivity, the MOSFET may be rendered inoperable. The spacers may act to prevent this.

Still referring to FIG. 13E, a channeled ion implantation process is performed to implant the p-type dopant ions into the semiconductor layer structure 160 to form the p-type trench shielding regions 152. As discussed, for example, in U.S. Pat. No. 11,075,264 (“the '264 patent”), the entire content of which is incorporated herein by reference, a channeled ion implantation process refers to an ion implantation process where the dopant ions are implanted along certain crystallographic axes in the silicon carbide semiconductor layer structure 160 where channels are formed, where a channel refers to an area where atoms are not present when viewed along the crystallographic axis. Channeled ion implantation may be performed by angling the ion source with respect to the semiconductor layer structure 160 so that the dopant ions are implanted along a desired crystallographic axis, as explained in further detail in the '264 patent. When dopant ions are implanted along channels in the crystallographic axis, the dopant ions travel, on average, much farther through the crystal lattice in the semiconductor layer structure 160 before they strike atoms within the crystal lattice than is the case when a random ion implantation process is performed. Consequently, the ions implanted in a channeled ion implantation process can be, on average, implanted to deeper depths while using lower implantation energies (which advantageously reduces damage to the silicon carbide semiconductor layer structure 160 from the implantation and which also reduces scattering of the dopant ions to unintended locations in the crystal lattice). In addition, channeled ion implantation typically results in little or no blooming of the implanted region with depth since the dopant ions end up striking fewer atoms and/or are more constrained within the channels. As explained in the '264 patent, there are crystallographic axes which support channeled ion implantation. When channeled ion implantation is used, not only may the dopant ions be implanted to deeper depths using less implantation energy, but the reduced scattering allows the implanted regions to have more vertical or inwardly angled sidewalls than is possible when standard (random) ion implantation techniques are used.

In 4H silicon carbide based devices, there are three sets of crystallographic axes which are amenable to channeled ion implantation, namely (1) the <0001> crystallographic axis, (2) the <11-23> crystallographic axis (and the symmetrically equivalent <−1-123>, <1-213>, <−12-13>, <2-1-13> and <−2113> crystallographic axes) and (3) the <11-20> crystallographic axis. The channeled ion implantation process to form the trench shielding regions 152 may be performed along any of these crystallographic axes of the semiconductor layer structure 160.

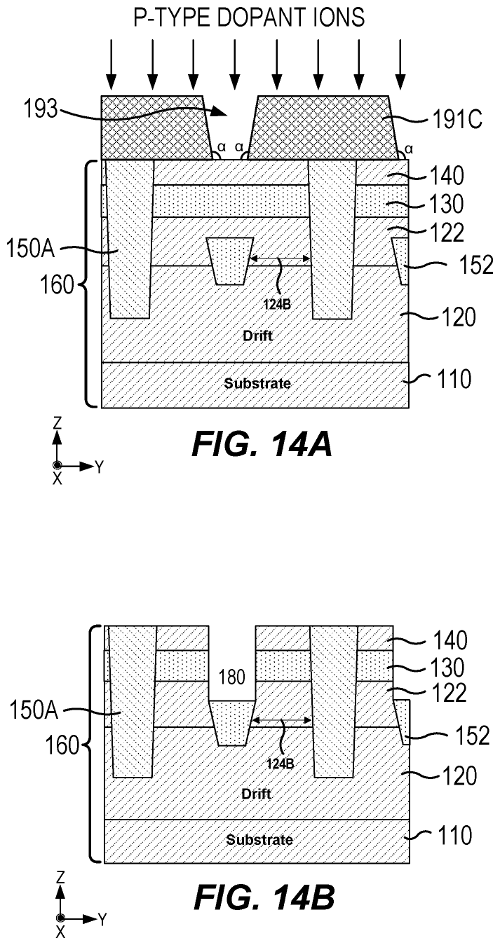

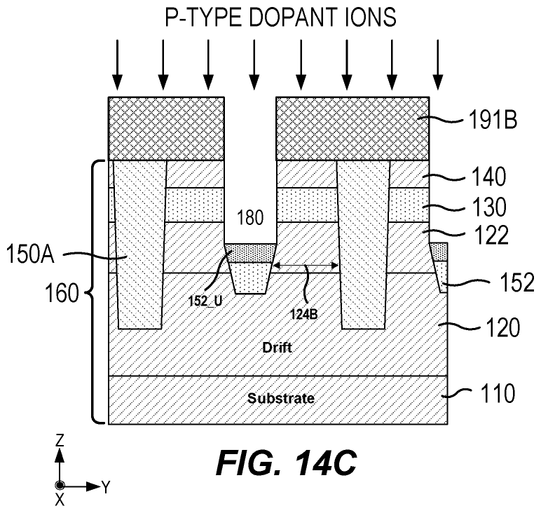

While FIG. 13E illustrates the trench shielding region 152 that has the sidewalls angled inwardly, it will be understood that the trench shielding region 152A having the substantially vertical sidewalls may also be formed by the channeled ion implantation process described above. The conditions of the channeled ion implantation process may be carefully controlled to form the trench shielding region 152 or the trench shielding region 152A. For example, during the channeled ion implantation process, an injection energy in which p-type dopant ions are accelerated before implantation, a doping dosage of the concentration of p-type dopant ions per unit area, and/or a projected range of the depth at which p-type dopant ions come to rest in the semiconductor layer structure 160 may be carefully selected to form the trench shielding region 152 or the trench shielding region 152A. After the channeled ion implantation process, for example, an annealing step may be performed to help provide the trench shielding region 152 or the trench shielding region 152A. As another example, the ion implantation mask 191B may be carefully designed to help form the trench shielding region 152 or the trench shielding region 152A. In some embodiments, the material(s) of the ion implantation mask 191B may be selected and/or the patterned openings in the ion implantation mask 191B may be designed to help provide the trench shielding region 152 or the trench shielding region 152A. For example, as will be discussed in greater detail below with reference to FIG. 14A, in some embodiments, an ion implantation mask may be patterned to have angled sidewalls along its openings during the channeled ion implantation process. The angled sidewalls of the ion implantation mask may be carefully patterned to help provide the desired profile of the trench shielding region 152 or the trench shielding region 152A.

Trench shielding regions 152 having the shapes shown in FIG. 13E may act to increase the JFET gaps 124B, which may lower the on-state resistance of the MOSFET and/or allow the unit cells thereof to be spaced more closely together by reducing the distance between adjacent gate trenches 180.

While the above description of FIG. 13E indicates that a channeled ion implantation process is used to form the trench shielding regions 152, it will be appreciated that embodiments of the present invention are not limited thereto. For example, in some other embodiments, a random ion implantation process may be used instead. However, due to the blooming that typically occurs with such an implantation process, it may be difficult to obtain trench shielding regions having inwardly angled or vertical sidewalls.

Referring to FIG. 13F, in some embodiments, the channeled ion implantation process may be performed to preliminarily form the trench shielding regions 152, and then p-type dopant ions may be implanted into upper portions of the trench shielding regions 152 using a random ion implantation process (i.e., a non-channeled ion implantation process). As a result, each trench shielding region 152 includes an upper portion 152_U having a higher second conductivity type (p) doping concentration than a lower portion of each trench shielding region 152. The more heavily doped upper portion 152_U of the trench shielding region 152 may provide increased protection for a gate oxide layer by reducing the electric field levels in areas where the gate oxide layer is most susceptible to breakdown. In some other embodiments, the random ion implantation process to form the upper portion 152_U of each trench shielding region 152 may alternatively be performed prior to the channeled ion implantation process described above with reference to FIG. 13E, and the remainder of each trench shielding region 152 may be formed thereafter by the channeled ion implantation process.

The upper portion 152_U of each trench shielding region 152 is formed by implanting p-type dopant ions into the semiconductor layer structure 160 using the random ion implantation process. Each trench shielding region 152 may thus be formed using both the channeled ion implantation process and the random ion implantation process. As shown in FIG. 13F, in some embodiments, the same ion implantation mask 191B used in the channeled ion implantation process may be used to form the upper portion 152_U of each trench shielding region 152 in the random ion implantation process. In some other embodiments, the ion implantation mask 191B may be removed after forming the trench shielding regions 152 in the channeled ion implantation process, and a new ion implantation mask may be used to form the upper portion 152_U of each trench shielding region 152 in the random ion implantation process. The ion implantation mask 191B includes openings therein above the gate trenches 180, and the upper portions 152_U of the trench shielding regions 152 are formed by implanting the p-type dopant ions into the gate trenches 180. During the random ion implantation process, the p-type dopant ions are implanted at high energy into the semiconductor layer structure 160. Unlike the channeled ion implantation process, the p-type dopant ions are not implanted in channels free of atoms, and thus as the p-type dopant ions pass into the semiconductor layer structure 160, they may collide with atoms in the crystal lattice. The p-type dopant ions may be implanted at an angle of 90° with respect to the upper surface of the semiconductor layer structure 160 (i.e., vertically) during the random ion implantation process. Since the upper portion 152_U of the trench shielding region 152 does not extend as deep in the semiconductor layer structure 160 as the remainder of the trench shielding region 152, the upper portion 152_U may exhibit significantly less blooming than that which may occur if an entirety of the trench shielding region 152 was formed by a random ion implantation process. As a result, there may be minimal to no impact on the JFET gaps 124B.

Referring back to FIG. 7B, the gate oxide layers 182 may be formed in the gate trenches 180 to cover the sidewalls and bottom surface of each gate trench 180. The gate electrodes 184 may be formed in the gate trenches 180 on the gate oxide layers 182. The intermetal dielectric layers 188 may be formed to cover each gate electrode 184. The source metallization layer 190 may be formed on the upper surface of the semiconductor layer structure 160 and on the intermetal dielectric layers 188. The drain pad 106 may be formed on the substrate 110 opposite the drift region 120.

While the description of FIGS. 13A-13F largely focuses on elements included in the power MOSFET 100E shown in FIG. 7B, it will be understood that the description of FIGS. 13A-13F is also applicable to elements included in the MOSFETs 100, 100A-100D, and 100F-100O, unless the context clearly indicates otherwise.

FIGS. 14A-14C are schematic cross-sectional views illustrating a method of fabricating a gate trench silicon carbide power MOSFET, according to some embodiments of the present invention. Like reference numbers in FIGS. 14A-14C refer to like elements described above.

Referring to FIG. 14A, in some embodiments, after the steps described above with reference to FIGS. 13A-13C, the trench shielding regions 152 are formed before forming the gate trenches 180. Further, in some embodiments, an ion implantation mask 191C that includes angled sidewalls may be used to form the trench shielding regions 152.

The ion implantation mask 191C may be patterned to form openings 193 therein that expose selected portions of the semiconductor layer structure 160. The openings 193 may be centered above locations in the semiconductor layer structure 160 in which the trench shielding regions 152 will be formed, but the openings 193 may be narrower than the intended width of the top portion of each trench shielding region 152. Notably, the sidewalls of portions of the mask 191C on both sides of the openings 193 are angled outwardly so that the width of these portions of the mask 191C increases as it comes closer to the semiconductor layer structure 160. As such, the sidewalls of the mask 191C that define each opening 193 are angled sidewalls that each defines an obtuse angle a with respect to the upper surface of the semiconductor layer structure 160 that is exposed through the respective opening 193, as shown in FIG. 14A. In some embodiments, the obtuse angle α is an angle between 1000 and 160°. The angled sidewalls of the mask 191C that define the openings 193 may be formed using various known etching techniques.

A thickness of the mask 191C is sufficient so that few or no dopant ions are able to pass through the full thickness of the mask 191C to implant into the semiconductor layer structure 160. However, since the sidewalls of the mask 191C that define the openings 193 are angled sidewalls, dopant ions that strike the sidewalls will not need to travel through the full thickness of the mask 191C to reach the semiconductor layer structure 160. As such, when the trench shielding regions 152 are formed using the channeled ion implantation process described above, some of the dopant ions that are implanted into the angled sidewalls of the mask 191C will travel through the mask 191C and be implanted into the semiconductor layer structure 160. Passing through the mask 191C, however, reduces the energy of these dopant ions (as they strike atoms within the mask 191C), and hence dopant ions that pass through the mask 191C before implanting into the semiconductor layer structure 160 will not, on average, travel as far (i.e., as deep) into the semiconductor layer structure 160 as dopant ions that are implanted through the openings 193 directly into the semiconductor layer structure 160. Moreover, the farther up one of the sidewalls a dopant ion is injected (i.e., the farther away from the bottoms of the openings 193), the less deep, on average, the dopant ions will implant into the semiconductor layer structure 160. As a result, the trench shielding regions 152 may be widest at the top and then narrow in width as they extend deeper in the semiconductor layer structure 160, as shown in FIG. 14A. In other words, the trench shielding regions 152 may have sidewalls that angle inwardly with increasing depth in the semiconductor layer structure 160. The ion implantation mask 191C may be removed after forming the trench shielding regions 152 in the channeled ion implantation process.

In the example embodiment of FIG. 14A, higher ion implantation energies may be used in the channeled ion implantation process to account for the trench shielding regions 152 being formed prior to the gate trenches 180. While FIG. 14A illustrates the trench shielding regions 152 that has the sidewalls angled inwardly, it will be understood that the trench shielding regions 152A having the substantially vertical sidewalls may also be formed as described above.

Referring to FIG. 14B, an etching process may be performed on the semiconductor layer structure 160 to form the gate trenches 180 in the semiconductor layer structure 160 on the respective trench shielding regions 152.

Referring to FIG. 14C, in some embodiments, the channeled ion implantation process may be performed to preliminarily form the trench shielding regions 152, and then p-type dopant ions may be implanted into an upper portion of each trench shielding region 152 using the random ion implantation process described above. The ion implantation mask 191B may be formed on the upper surface of the semiconductor layer structure 160 and patterned to form openings therein above the gate trenches 180 in which the p-type dopant ions arc implanted. As a result, each trench shielding region 152 includes the upper portion 152_U that has a higher second conductivity type (p) doping concentration than a lower portion of each trench shielding region 152. Each trench shielding region 152 may thus be formed using both the channeled ion implantation process and the random ion implantation process. The ion implantation mask 191B may then be removed, and the gate oxide layers 182, the gate electrodes 184, the intermetal dielectric layers 188, the source metallization layer 190, and the drain pad 106 may be formed as described above.

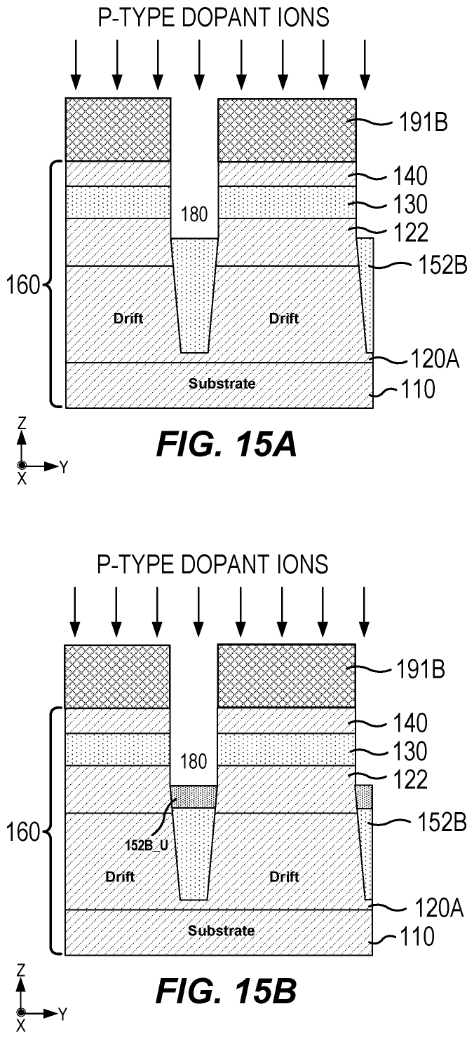

FIGS. 15A and 15B are schematic cross-sectional views illustrating a method of fabricating a gate trench silicon carbide power MOSFET, according to some embodiments of the present invention. Like reference numbers in FIGS. 15A and 15B refer to like elements described above.

Referring to FIG. 15A, in some embodiments, after the steps described above with reference to FIGS. 13A-13D, the moderately or heavily-doped p-type silicon carbide trench shielding regions 152B are formed in the semiconductor layer structure 160 underneath each gate trench 180 by implanting p-type dopant ions into the gate trenches 180, thereby providing a super junction structure in the drift region 120A. In this case, the steps described above with reference to FIG. 13C to form the support shields 150A may be omitted. The ion implantation mask 191B is formed on the upper surface of the semiconductor layer structure 160 and is patterned to form openings therein above the gate trenches 180. The trench shielding regions 152B are formed using the channeled ion implantation process described above. In the example embodiment of FIG. 15A, higher ion implantation energies may be used in the channeled ion implantation process so that the trench shielding regions 152B extend deeper into the drift region 120A to provide the super junction structure therein. The channeled ion implantation process may allow the trench shielding regions 152B to extend deeper into the drift region 120A than a random (non-channeled) ion implantation process would.

The channeled ion implantation process used to form the trench shielding regions 152B is performed in the gate trenches 180, which may provide two advantages. First, since the p-type dopant ions are implanted into the gate trenches 180 instead of an upper surface of the semiconductor layer structure 160, the trench shielding regions 152B may extend deeper into the drift region 120A while using the same amount of energy or less energy in the channeled ion implantation process. Second, the trench shielding regions 152B may be aligned with the gate trenches 180 along all or substantially all of the length of the gate trenches 180 in the first direction X (i.e., into the page in FIG. 15A). The trench shielding regions 152B may thus provide increased protection for gate oxide layers along all or substantially all of their length while also providing the super junction structure in the drift region 120A. While FIG. 15A illustrates the trench shielding region 152B that has the sidewalls angled inwardly, it will be understood that the trench shielding region 152C having the substantially vertical sidewalls may also be formed as described above.

Referring to FIG. 15B, in some embodiments, the channeled ion implantation process may be performed to preliminarily form the trench shielding regions 152B, and then p-type dopant ions may be implanted into an upper portion of each trench shielding region 152B using the random ion implantation process described above. As a result, each trench shielding region 152B includes an upper portion 152B_U that has a higher second conductivity type (p) doping concentration than a lower portion of each trench shielding region 152B. Each trench shielding region 152B may thus be formed using both the channeled ion implantation process and the random ion implantation process. The ion implantation mask 191B may then be removed, and the gate oxide layers 182, the gate electrodes 184, the intermetal dielectric layers 188, the source metallization layer 190, and the drain pad 106 may be formed as described above. In some other embodiments, the random ion implantation process to form the upper portion 152B_U of each trench shielding region 152B may alternatively be performed prior to the channeled ion implantation process, and the remainder of each trench shielding region 152B may be formed thereafter by the channeled ion implantation process.

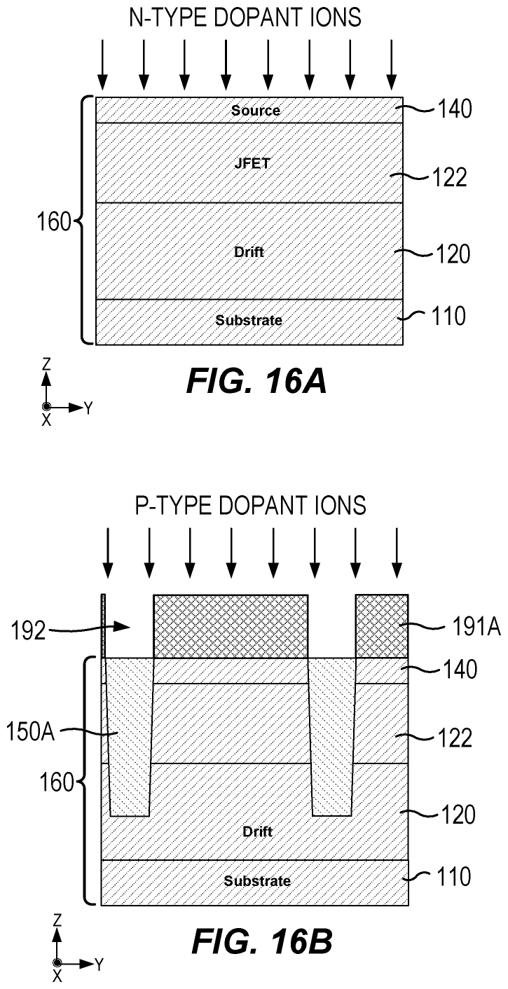

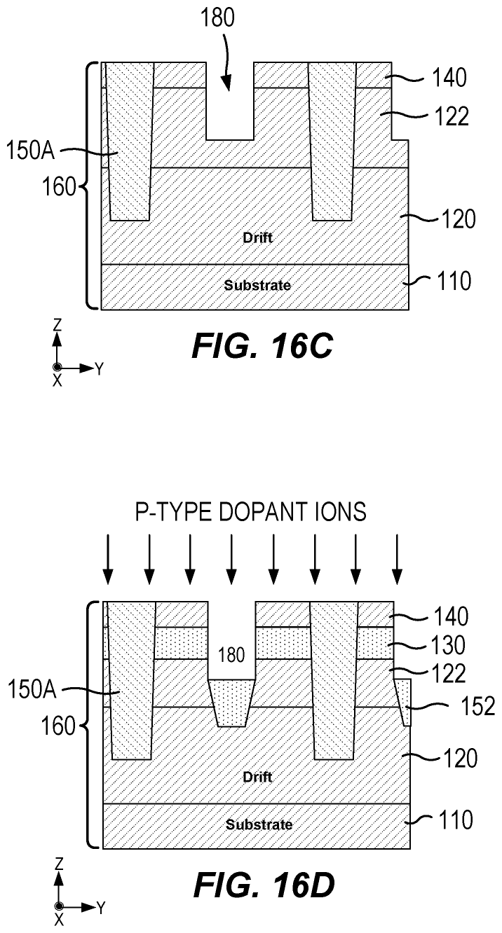

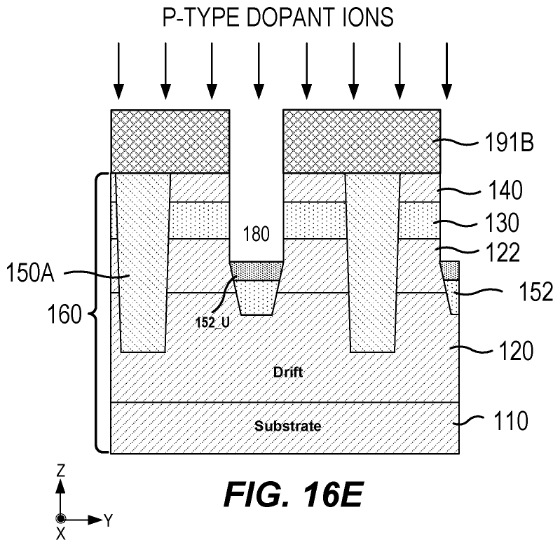

FIGS. 16A-16E are schematic cross-sectional views illustrating a method of fabricating a gate trench silicon carbide power MOSFET, according to some embodiments of the present invention. Like reference numbers in FIGS. 16A-16E refer to like elements described above.

Referring to FIG. 16A, the substrate 110, the drift region 120, and the JFET region 122 are formed as described above with reference to FIG. 13A. Then, different from that described above with reference to FIG. 13A, the source region 140 is formed in an upper portion of the drift region 120 (i.e., in an upper portion of the JFET region 122). The n-type source region 140 is typically formed via ion implantation as this may provide a more consistent doping density, as shown in FIG. 16A, but can alternatively be formed by epitaxial growth on the silicon carbide drift region 120. The silicon carbide substrate 110, drift region 120, JFET region 122 and source region 140, along with the various regions formed therein such as a well region, support shields, and trench shielding regions (discussed below), comprise a semiconductor layer structure 160.

Referring to FIG. 16B, the silicon carbide support shields 150A are formed by implanting p-type dopant ions into the semiconductor layer structure 160. To form the support shields 150A, the ion implantation mask 191A is formed on the upper surface of the semiconductor layer structure 160 and is patterned to form the openings 192 therein above the regions of the semiconductor layer structure 160 where the support shields 150A are to be formed. The support shields 150A are then formed by ion implantation, and the ion implantation mask 191A is thereafter removed. The support shields 150A may be formed by the channeled ion implantation process discussed above. Although not shown, in some other embodiments, the support shields 150 instead of the support shields 150A may be formed by implanting p-type dopant ions into the semiconductor layer structure 160. In this case, the support shields 150 may be formed by the random ion implantation process described above.

Referring to FIG. 16C, an etching process may be carried out to form the plurality of gate trenches 180 in the upper surface of the semiconductor layer structure 160. For example, the formation of the gate trenches 180 may convert the source region 140 and the JFET region 122 into the plurality of source regions 140 and the plurality of JFET regions 122, respectively.

Referring to FIG. 16D, the channeled ion implantation process described above is performed to implant p-type dopant ions into the semiconductor layer structure 160. Different from that described above with reference to FIG. 13E, this ion implantation step is performed without an ion implantation mask. The p-type dopants are implanted into and through the heavily-doped n-type source regions 140 and into the underlying drift region 120 to form the moderately-doped well regions 130 in the upper portion of the drift region 120 (i.e., in the upper portion of the JFET regions 122) underneath the source regions 140. The portions of the well regions 130 that are adjacent the gate trenches 180 act as a channel. The p-type dopants are also implanted into the portions of the drift region 120 (i.e., the portions of the JFET regions 122) that are underneath the bottom surfaces of the gate trenches 180 to form the trench shielding regions 152 that extend thereunder. In the example embodiment of FIG. 16D, the channeled ion implantation process may be performed using higher ion implantation energies, since the p-type dopants are implanted through the n-type source regions 140 to form the well regions 130 thereunder.

Since the well regions 130 and the trench shielding regions 152 are formed together (i.e., simultaneously) using the same channeled ion implantation process, the doping profile of the p-type dopants in the well regions 130 will substantially match (i.e., match within 15%) the doping profile of the p-type dopants in the lower portions of the trench shielding regions 152. Herein, a doping profile of a region of a semiconductor layer structure (e.g., the doping profile of the well regions 130 or the trench shielding regions 152) refers to the variation in the concentration of a certain type of conductivity type dopants as a function of depth. Thus, the doping profile may be depicted graphically using a two-dimensional graph that has a curve that shows the concentration of dopants of the specified conductivity-type as a function of distance in the depth direction from a reference plane such as, for example, the upper surface of the semiconductor layer structure 160. It will be appreciated that doping profiles for a region are taken through a central portion of the region that does not abut another region as opposed to an edge portion of the region as edge effects may result in unintended variations in the doping profile that are not representative of the doping profile of the region.

Referring to FIG. 16E, in some embodiments, the channeled ion implantation process may be performed to preliminarily form the trench shielding regions 152, and then p-type dopant ions may be implanted into an upper portion of each trench shielding region 152 using the random ion implantation process described above. As a result, each trench shielding region 152 includes the upper portion 152_U that has a higher second conductivity type (p) doping concentration than a lower portion of each trench shielding region 152. Each trench shielding region 152 may thus be formed using both the channeled ion implantation process and the random ion implantation process. The ion implantation mask 191B may then be removed, and the gate oxide layers 182, the gate electrodes 184, the intermetal dielectric layers 188, the source metallization layer 190, and the drain pad 106 may be formed as described above. In some other embodiments, the random ion implantation process to form the upper portion 152_U of each trench shielding region 152 may alternatively be performed prior to the channeled ion implantation process, and the well regions 130 may be formed together (i.e., simultaneously) using the same random ion implantation process. The remainder of each trench shielding region 152 may be formed thereafter by the channeled ion implantation process.

It will be appreciated that the processing steps discussed above with reference to FIGS. 13A-13F, 14A-14C, 15A-15B, and 16A-16E could be performed in different orders in further embodiments. Thus, it will be appreciated that various of the processing steps may be carried out in different orders than that shown. It will also be appreciated that some of the processing steps could be omitted in other embodiments, and/or that other processing steps may be added to the method.

As described above, one technique for forming trenching shielding regions that have inwardly angled or substantially vertical sidewalls with increasing depth in the semiconductor layer structure is to use a channeled ion implantation process to form the trench shielding regions. It will be appreciated, however, that embodiments of the present invention are not necessarily limited thereto. For example, in other embodiments, the trench shielding regions may be formed to have sidewalls that angle outwardly with increasing depth in the semiconductor layer structure, and either before or after this ion implantation process, n-type dopants are implanted into the semiconductor layer structure using a buried random ion implantation process. The blooming that occurs with increasing depth with the random ion implantation process implants the n-type dopants into the outer edges of the trench shielding regions that compensate the p-type dopants, thereby converting outer edges of the trench shielding regions into n-type semiconductor material. The extent to which this occurs increases with increasing depth as the blooming increases with increasing depth. As a result, the trench shielding regions may have inwardly angled or substantially vertical sidewalls with increasing depth in the semiconductor layer structure.

Example embodiments of the present invention are primarily described above with respect to cross-sectional diagrams. It will be appreciated that in each of the depicted embodiments of the present invention the support shields, the trench shielding regions, the gate trenches, etc. may be elongated structures that extend continuously into the page in the figures across the active region of the semiconductor devices. However, it will also be appreciated that the support shields and/or the trench shielding regions may instead be segmented structures in other embodiments that have sections removed so that these structures do not extend continuously into the pages in the figures, but instead are structures with multiple collinear segments extending into the page.

In the description above, each example embodiment has a certain conductivity type. It will be appreciated that opposite conductivity type devices may be formed by simply reversing the conductivity of the n-type and p-type layers in each of the above embodiments.

Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which example embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like reference numbers refer to like elements throughout the Specification.

Herein, the term “plurality” means two or more. Herein, “substantially” means within +/−10%.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising”, “includes”, “including”, “has”, and/or “having” when used herein, specify the presence of stated features, integers, steps, operations, elements, components, and/or groups, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an clement is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation. the scope of the invention being set forth in the following claims.

1. A semiconductor device, comprising:
a semiconductor layer structure that comprises a drift region having a first conductivity type and a trench shielding region having a second conductivity type; and
a gate trench extending in a longitudinal direction in the semiconductor layer structure,
wherein the trench shielding region extends in the longitudinal direction underneath the gate trench, and at least a portion of the trench shielding region comprises sidewalls that angle inwardly with increasing distance from the gate trench.

2. The semiconductor device of claim 1, wherein the portion of the trench shielding region comprises at least a lower half of the trench shielding region.

3. The semiconductor device of claim 2, wherein the sidewalls of the portion of the trench shielding region angle inwardly with increasing distance from the gate trench in a direction perpendicular to a lower surface of the semiconductor layer structure.

4. The semiconductor device of claim 2, wherein a maximum width of the portion of the trench shielding region is less than or equal to a maximum width of the gate trench.

5. The semiconductor device of claim 2, wherein the semiconductor layer structure further comprises first and second support shields having the second conductivity type and extending in the longitudinal direction on first and second sides of the gate trench, respectively.

6. The semiconductor device of claim 5, wherein a portion of the drift region is between the first support shield and the trench shielding region and has a width that is substantially constant or increases with increasing depth in the semiconductor layer structure.

7. The semiconductor device of claim 6, wherein the width of the portion of the drift region increases with increasing depth in the semiconductor layer structure.

8. The semiconductor device of claim 5, wherein the first and second support shields have respective widths that are substantially constant or decrease with increasing depth in the semiconductor layer structure.

9. The semiconductor device of claim 5, wherein the first and second support shields have respective widths that increase with increasing depth in the semiconductor layer structure.

10. The semiconductor device of claim 2, wherein an upper portion of the trench shielding region is between the gate trench and a lower portion of the trench shielding region and has a higher second conductivity type doping concentration than the lower portion of the trench shielding region.

11. The semiconductor device of claim 2, further comprising a gate oxide layer and a gate electrode in the gate trench, wherein the semiconductor layer structure further comprises a well region having the second conductivity type on the drift region and a source region having the first conductivity type on the well region.

12. The semiconductor device of claim 2, wherein the drift region comprises silicon carbide.

13. A semiconductor device, comprising:
a semiconductor layer structure that comprises a drift region having a first conductivity type and a trench shielding region having a second conductivity type; and
a gate trench extending in a longitudinal direction in the semiconductor layer structure,
wherein the trench shielding region extends underneath the gate trench in the longitudinal direction, the trench shielding region comprising endwalls that oppose each other along the longitudinal direction and are oblique with respect to a lower surface of the semiconductor layer structure.

14. The semiconductor device of claim 13, wherein the endwalls of the trench shielding region extend substantially parallel to each other.

15. The semiconductor device of claim 13, wherein the endwalls of the trench shielding region are adjacent an inactive region of the semiconductor device.

16. The semiconductor device of claim 13, wherein one of the endwalls of the trench shielding region extends past an endwall of the gate trench in the longitudinal direction.

17. The semiconductor device of claim 13, wherein one of the endwalls of the trench shielding region comprises a lower portion that is free of vertical overlap with the gate trench.

18. A semiconductor device, comprising:
a semiconductor layer structure that comprises a drift region having a first conductivity type and a trench shielding region having a second conductivity type; and
a gate trench extending in a longitudinal direction in the semiconductor layer structure,
wherein the trench shielding region extends underneath the gate trench in the longitudinal direction, the trench shielding region comprising an endwall that extends past an endwall of the gate trench in the longitudinal direction.

19. The semiconductor device of claim 18, wherein the endwall of the trench shielding region is one of a pair of endwalls of the trench shielding region that oppose each other along the longitudinal direction and are oblique with respect to a lower surface of the semiconductor layer structure.

20. The semiconductor device of claim 18, wherein the endwall of the trench shielding region comprises a lower portion that is free of vertical overlap with the gate trench.

21. The semiconductor device of claim 18, wherein the endwall of the trench shielding region is adjacent an inactive region of the semiconductor device.

18. The semiconductor device of claim 18, wherein the endwall of the trench shielding region is oblique with respect to a lower surface of the semiconductor layer structure.

23-56. (canceled)
